(19) United States
(12) Patent Application Publication
(10) Pub. No.: US 2023/0029405 A1
(43) Pub. Date: Jan. 26, 2023

(54) Early-Life Diagnostics For Fast Battery Formation Protocols And Their Impacts To Long-Term Aging

(71) Applicant: THE REGENTS OF THE UNIVERSITY OF MICHIGAN, ANN ARBOR, MI (US)

(72) Inventors: ANNA G. STEFANOPOULOU, ANN ARBOR, MI (US); ANDREW WENG, ANN ARBOR, MI (US); PEYMAN MOHTAT, ANN ARBOR, MI (US); PETER M. ATTIA, STANFORD, CA (US); VALENTIN SULZER, ANN ARBOR, MI (US); SUHAK LEE, ANN ARBOR, MI (US); GREG LESS, ANN ARBOR, MI (US)

(21) Appl. No.: 17/859,390

(22) Filed: Jul. 7, 2022

Related U.S. Application Data
(60) Provisional application No. 63/219,476, filed on Jul. 8, 2021.

(51) Int. Cl. G01R 31/389; G01R 31/367; G01R 31/396; H01M 10/44; H01M 10/48

(52) U.S. Cl. CPC G01R 31/389; G01R 31/367; G01R 31/396; H01M 10/446; H01M 10/48

(57) ABSTRACT

The present disclosure relates to a method for optimizing the formation protocol of a battery. The method can include the steps of: (a) providing a battery cell structure comprising an anode, an electrolyte, and a cathode including cations that move from the cathode to the anode during charging; (b) performing a first charge of the battery cell structure using a predetermined formation protocol to create a formed battery cell; and (c) determining a cell internal resistance of the formed battery cell. Therefore, one can compare the cell internal resistances of two battery cells formed by using identical battery cell structures and different formation protocols, and select a formation protocol if the first cell internal resistance of a first formed battery is greater than or less than the second cell internal resistance of a second formed battery.

### CROSS-REFERENCES TO RELATED APPLICATIONS

This application is based on, claims benefit of, and claims priority to U.S. Application No. 63/219,476 filed on Jul. 8, 2021, which is hereby incorporated by reference herein in its entirety for all purposes.

### STATEMENT REGARDING FEDERALLY SPONSORED RESEARCH

This invention was made with government support under Grant Number 176224 awarded by the National Science Foundation. The government has certain rights in the invention.

### BACKGROUND OF THE INVENTION

### 1. Field of the Invention

This invention relates to electrochemical devices, such as lithium ion batteries and lithium metal batteries. This invention also relates to methods for making such electrochemical devices.

### 2. Description of the Related Art

With the increasing demand for electric vehicles, global lithium-ion battery manufacturing capacity is quickly approaching the terawatt-hour scale [Ref. 1-3]. A key step in battery manufacturing is formation/aging, which has been estimated to account for up to 30% of total manufacturing costs [Ref. 4-8]. The formation/aging process involves charging and discharging hundreds of thousands of cells in environmentally controlled chambers, an expensive process that takes days to weeks to complete, but is necessitated by its impact on battery performance and lifetime [Ref. 9-14]. Given the high cost burden, manufacturers are incentivized to develop new formation processes that decrease the total time taken for formation and aging. A variety of fast formation strategies have been studied in academic literature, which employ some combination of rapid charge-discharge cycles, restricted voltage windows, and optimized temperature [Ref. 10, 15-26]. Recent studies have shown that formation time could be decreased while preserving battery lifetime [Ref. 16, 22], although conclusions remain tenuous due to small samples sizes used in these studies.

In real manufacturing settings, a “one size fits all” formation protocol is unlikely to exist, since different electrolyte systems, electrode designs, and active material choices, combine together to create differences in charging capability, electrode wettability, and solid electrolyte interphase (SEI) reaction pathways. Cycle life testing often takes months to complete which poses a significant barrier to the adoption of new, potentially cost-saving formation protocols. Methods for screening the impact of new formation protocols on battery lifetime quickly and cheaply are therefore highly desirable. While many advanced cell characterization techniques exist, including volume change detection [Ref. 27], impedance spectroscopy [Ref. 15], acoustic measurements [Ref. 28-31] and X-ray tomography [Ref. 32], these signals can be costly to implement since the metrology will need to be deployed at scale in the battery factory.

What is needed therefore is improved early-life diagnostics that enable faster battery formation protocols that can still achieve a higher cycle life in the formed battery cell.

### SUMMARY OF THE INVENTION

Increasing the speed of battery formation can significantly lower battery manufacturing costs. However, adopting faster formation protocols in real manufacturing settings is challenging due to a lack of cheap, rapid diagnostic signals that can inform possible impacts to long term battery lifetime. In this disclosure, we identify the cell resistance measured at low states of charge as an early-life diagnostic feature. We show that this signal correlates to cycle life and can enhance the accuracy of data-driven battery lifetime models. The signal can be measured using ordinary testing equipment at the end of manufacturing lines and at zero additional costs. We elucidate a physical connection between low-state of charge (SOC) resistance and the amount of lithium consumed during formation, which suggests that the technique can be used to evaluate any manufacturing process that could affect the total lithium consumed during formation. This disclosure demonstrates that, despite decades of research, carefully engineered current-voltage features signals can still provide new and ‘free’ insights into battery degradation at the beginning of life.

In one aspect, the present disclosure provides a method for forming a battery. The method comprises: (a) providing a battery cell structure comprising an anode, an electrolyte, and a cathode including cations that move from the cathode to the anode during charging; and (b) performing a first charge of the battery cell structure using a predetermined formation protocol to create a formed battery cell, wherein the predetermined formation protocol is determined by: (i) determining a first cell internal resistance of a first reference battery cell formed by using a first cell structure identical to the battery cell structure and performing a first initial charge of the first cell structure using a first formation protocol, (ii) determining a second cell internal resistance of a second reference battery cell formed by using a second cell structure identical to the battery cell structure and performing a second initial charge of the second cell structure using a second formation protocol, wherein the second formation protocol is different from the first formation protocol, and (iii) selecting the predetermined formation protocol to correspond to the first formation protocol if the first cell internal resistance is greater than or less than the second cell internal resistance, and selecting the predetermined formation protocol to correspond to the second formation protocol if the second cell internal resistance is greater than or less than the first cell internal resistance. In one version of this embodiment, the predetermined formation protocol is selected to correspond to the first formation protocol if the first cell internal resistance is less than the second cell internal resistance, and the predetermined formation protocol is selected to correspond to the second formation protocol if the second cell internal resistance is less than the first cell internal resistance.

In the method, the first cell internal resistance and the second cell internal resistance can be determined using a direct current resistance measurement. In the method, the first cell internal resistance and the second cell internal resistance can be determined using an alternating current resistance measurement. In one version of the method, the battery cell structure provided in step (a) lacks a solid electrolyte interphase between the electrolyte and the anode.

In the method, the first cell internal resistance of the first reference battery cell can be determined at a first state of charge of the first reference battery cell of 15% or lower, and the second cell internal resistance of the second reference battery cell can be determined at a second state of charge of the second reference battery cell of 15% or lower, wherein the first state of charge and the second state of charge are the same. In the method, the first cell internal resistance of the first reference battery cell can be determined using a first series of discharge pulses, and the second cell internal resistance of the second reference battery cell can be determined using a second series of discharge pulses, wherein the first series of discharge pulses and the second series of discharge pulses are the same. The discharge pulses can have a pulse duration less than 1 minute.

In the method, the first cell internal resistance of the first reference battery cell can be determined using a first series of charge pulses, and the second cell internal resistance of the second reference battery cell can be determined using a second series of charge pulses, wherein the first series of charge pulses and the second series of charge pulses are the same. The charge pulses can have a pulse duration less than 1 minute. In the method, the first cell internal resistance of the first reference battery cell can be determined before a second charge of the first reference battery cell, and the second cell internal resistance of the second reference battery cell can be determined before a second charge of the second reference battery cell. In the method, a charging current of the predetermined formation protocol can be based at least in part on a percentage of a capacity of the formed battery cell.

In the method, the cations can be lithium cations. The anode can comprise an anode material selected from graphite, lithium titanium oxide, hard carbon, tin/cobalt alloys, silicon/carbon, or lithium metal. The electrolyte can comprises a liquid electrolyte including a lithium compound in an organic solvent, and the cathode can comprise a cathode active material selected from (i) lithium metal oxides wherein the metal is one or more aluminum, cobalt, iron, manganese, nickel and vanadium, (ii) lithium-containing phosphates having a general formula LiMPO₄ wherein M is one or more of cobalt, iron, manganese, and nickel, and (iii) materials having a formula LiNiₓMn_{y}Co_{z}O₂, wherein x+y+z=1 and x:y:z=1:1:1 (NMC 111), x:y:z=4:3:3 (NMC 433), x:y:z=5:2:2 (NMC 522), x:y:z=5:3:2 (NMC 532), x:y:z=6:2:2 (NMC 622), or x:y:z=8:1:1 (NMC 811). The anode can comprise graphite; the lithium compound can selected from LiPF₆, LiBF₄, LiClO₄, lithium bis(fluorosulfonyl)imide (LiFSI), LiN(CF₃SO₂)₂ (LiTFSI), and LiCF₃SO₃ (LiTf); the organic solvent can be selected from carbonate based solvents, ether based solvents, ionic liquids, and mixtures thereof, the carbonate based solvent can be selected from the group consisting of dimethyl carbonate, diethyl carbonate, ethyl methyl carbonate, dipropyl carbonate, methylpropyl carbonate, ethylpropyl carbonate, methylethyl carbonate, ethylene carbonate, propylene carbonate, and butylene carbonate, and mixtures thereof; and the ether based solvent can be selected from the group consisting of diethyl ether, dibutyl ether, monoglyme, diglyme, tetraglyme, 2-methyltetrahydrofuran, tetrahydrofuran, 1,3-dioxolane, 1,2-dimethoxyethane, and 1,4-dioxane and mixtures thereof.

In another aspect, the present disclosure provides a method for predicting cycle life of a battery. The method comprises: (a) providing a battery cell structure comprising an anode, an electrolyte, and a cathode including cations that move from the cathode to the anode during charging; (b) performing a first charge of the battery cell structure using a predetermined formation protocol to create a formed battery cell; (c) determining a cell internal resistance of the formed battery cell; and (d) comparing the cell internal resistance of the formed battery cell to a characteristic curve of measured or model predicted cycle life versus cell internal resistance of reference battery cells formed by using cell structures identical to the battery cell structure and reference formation protocols different from the predetermined formation protocol.

In the method, the cell internal resistance can be determined using a direct current resistance measurement. In the method, the cell internal resistance can be determined using an alternating current resistance measurement. In one version of the method, the battery cell structure provided in step (a) lacks a solid electrolyte interphase between the electrolyte and the anode.

In the method, the cell internal resistance of the formed battery cell can be determined at a first state of charge of the formed battery cell of 15% or lower. In the method, the cell internal resistance of the formed battery cell can be determined using a first series of discharge pulses. The discharge pulses can have a pulse duration less than 1 minute. A charging current of the predetermined formation protocol can be based at least in part on a percentage of a capacity of the formed battery cell.

In the method, the cell internal resistance of the formed battery cell can be determined using a first series of charge pulses. The charge pulses can have a pulse duration less than 1 minute. In the method, the cell internal resistance of the formed battery cell can be determined before a second charge of the formed battery cell.

In the method, the cations can be lithium cations. The anode can comprise an anode material selected from graphite, lithium titanium oxide, hard carbon, tin/cobalt alloys, silicon/carbon, or lithium metal. The electrolyte can comprises a liquid electrolyte including a lithium compound in an organic solvent, and the cathode can comprise a cathode active material selected from (i) lithium metal oxides wherein the metal is one or more aluminum, cobalt, iron, manganese, nickel and vanadium, (ii) lithium-containing phosphates having a general formula LiMPO₄ wherein M is one or more of cobalt, iron, manganese, and nickel, and (iii) materials having a formula LiNiₓMn_{y}Co_{z}O₂, wherein x+y+z=1 and x:y:z=1:1:1 (NMC 111), x:y:z=4:3:3 (NMC 433), x:y:z=5:2:2 (NMC 522), x:y:z=5:3:2 (NMC 532), x:y:z=6:2:2 (NMC 622), or x:y:z=8:1:1 (NMC 811). The anode can comprise graphite; the lithium compound can selected from LiPF₆, LiBF₄, LiClO₄, lithium bis(fluorosulfonyl)imide (LiFSI), LiN(CF₃SO₂)₂ (LiTFSI), and LiCF₃SO₃ (LiTf); the organic solvent can be selected from carbonate based solvents, ether based solvents, ionic liquids, and mixtures thereof, the carbonate based solvent can be selected from the group consisting of dimethyl carbonate, diethyl carbonate, ethyl methyl carbonate, dipropyl carbonate, methylpropyl carbonate, ethylpropyl carbonate, methylethyl carbonate, ethylene carbonate, propylene carbonate, and butylene carbonate, and mixtures thereof; and the ether based solvent can be selected from the group consisting of diethyl ether, dibutyl ether, monoglyme, diglyme, tetraglyme, 2-methyltetrahydrofuran, tetrahydrofuran, 1,3-dioxolane, 1,2-dimethoxyethane, and 1,4-dioxane and mixtures thereof.

In yet another aspect, the present disclosure provides a method for determining whether a first predicted cycle life of a first battery cell is greater than a second predicted cycle life of a second battery cell. The method comprises: (a) providing a first battery cell structure comprising an anode, an electrolyte, and a cathode including cations that move from the cathode to the anode during charging; (b) determining a first cell internal resistance of a first battery cell formed by performing a first initial charge of the first battery cell structure using a formation protocol; (c) determining a second cell internal resistance of a second battery cell formed by performing a second initial charge of a second battery cell structure identical to the first battery cell structure; and (d) determining that a first predicted cycle life of the first battery cell is greater than a second predicted cycle life of the second battery cell if the first cell internal resistance is greater than or less than the second cell internal resistance. In one version of this embodiment, a first predicted cycle life of the first battery cell is determined to be greater than a second predicted cycle life of the second battery cell if the first cell internal resistance is less than the second cell internal resistance.

In the method, a first predicted cycle life of the first battery cell can be determined to be greater than a second predicted cycle life of the second battery cell if the first cell internal resistance is less than the second cell internal resistance. In the method, the first cell internal resistance and the second cell internal resistance can be determined using a direct current resistance measurement. In the method, the first cell internal resistance and the second cell internal resistance can be determined using an alternating current resistance measurement.

In one version of the method, the first battery cell structure provided in step (a) lacks a solid electrolyte interphase between the electrolyte and the anode.

In the method, the first cell internal resistance of the first reference battery cell can be determined at a first state of charge of the first reference battery cell of 15% or lower, and the second cell internal resistance of the second reference battery cell can be determined at a second state of charge of the second reference battery cell of 15% or lower, wherein the first state of charge and the second state of charge are the same. In the method, the first cell internal resistance of the first battery cell can be determined using a first series of discharge pulses, and the second cell internal resistance of the second battery cell can be determined using a second series of discharge pulses, wherein the first series of discharge pulses and the second series of discharge pulses are the same. The discharge pulses can have a pulse duration less than 1 minute.

In the method, the first cell internal resistance of the first battery cell can be determined using a first series of charge pulses, and the second cell internal resistance of the second battery cell can be determined using a second series of charge pulses, wherein the first series of charge pulses and the second series of charge pulses are the same. The charge pulses can have a pulse duration less than 1 minute. A charging current of the formation protocol can be based at least in part on a percentage of a capacity of the formed battery cell.

In the method, the first cell internal resistance of the first battery cell can be determined before a second charge of the first battery cell, and the second cell internal resistance of the second battery cell can be determined before a second charge of the second battery cell.

In the method, the cations can be lithium cations. The anode can comprise an anode material selected from graphite, lithium titanium oxide, hard carbon, tin/cobalt alloys, silicon/carbon, or lithium metal. The electrolyte can comprises a liquid electrolyte including a lithium compound in an organic solvent, and the cathode can comprise a cathode active material selected from (i) lithium metal oxides wherein the metal is one or more aluminum, cobalt, iron, manganese, nickel and vanadium, (ii) lithium-containing phosphates having a general formula LiMPO₄ wherein M is one or more of cobalt, iron, manganese, and nickel, and (iii) materials having a formula LiNiₓMn_{y}Co_{z}O₂, wherein x+y+z=1 and x:y:z=1:1:1 (NMC 111), x:y:z=4:3:3 (NMC 433), x:y:z=5:2:2 (NMC 522), x:y:z=5:3:2 (NMC 532), x:y:z=6:2:2 (NMC 622), or x:y:z=8:1:1 (NMC 811). The anode can comprise graphite; the lithium compound can selected from LiPF₆, LiBF₄, LiClO₄, lithium bis(fluorosulfonyl)imide (LiFSI), LiN(CF₃SO₂)₂ (LiTFSI), and LiCF₃SO₃ (LiTf); the organic solvent can be selected from carbonate based solvents, ether based solvents, ionic liquids, and mixtures thereof, the carbonate based solvent can be selected from the group consisting of dimethyl carbonate, diethyl carbonate, ethyl methyl carbonate, dipropyl carbonate, methylpropyl carbonate, ethylpropyl carbonate, methylethyl carbonate, ethylene carbonate, propylene carbonate, and butylene carbonate, and mixtures thereof; and the ether based solvent can be selected from the group consisting of diethyl ether, dibutyl ether, monoglyme, diglyme, tetraglyme, 2-methyltetrahydrofuran, tetrahydrofuran, 1,3-dioxolane, 1,2-dimethoxyethane, and 1,4-dioxane and mixtures thereof.

In still another aspect, the present disclosure provides a method for predicting cycle life of a battery. The method comprises: (a) providing a battery cell structure comprising an anode, an electrolyte, and a cathode including cations that move from the cathode to the anode during charging; (b) performing a first charge of the battery cell structure using a predetermined formation protocol to create a formed battery cell; (c) determining a cell internal resistance of the formed battery cell; (d) determining a cycle life of the formed battery cell by cycling the formed battery cell to an end of life; (e) repeating steps (a) through (d) for one or more additional battery cell structures; and (f) training a statistical model taking the cell internal resistance and cycle life of each of the formed battery cell and additional formed battery cells as input and providing a prediction of cycle life for another battery cell.

In the method, step (f) can further comprise training the statistical model using one or more features selected from: (i) electrical data from the battery formation process, including voltage decay during rest, differential capacity, differential voltage, and (ii) measurements including cell expansion and contraction, and acoustic response. The cations can be lithium cations.

In yet another aspect, the present disclosure provides a method for optimizing a battery formation protocol. The method comprises: (a) providing a battery cell structure comprising an anode, an electrolyte, and a cathode including cations that move from the cathode to the anode during charging; (b) performing a first charge of the battery cell structure using a predetermined formation protocol to create a formed battery cell; (c) measuring a first group of current-voltage signals during or immediately after the formation protocol; (d) measuring a second group of current-voltage signals of the formed battery cell after cycling the formed battery cell to an end of life; (e) repeating steps (a) through (d) for one or more additional battery cell structures; and (f) creating a statistical model taking the first group of current-voltage signals and the second group of current-voltage signals of each of the formed battery cell and additional formed battery cells as input and providing an optimized battery formation protocol for another battery cell. Step (f) can further comprise training the statistical model using one or more features selected from: (i) electrical data from the battery formation process, including voltage decay during rest, differential capacity, differential voltage, and (ii) measurements including cell expansion and contraction, and acoustic response.

In the method, the formation protocol can comprise a charging current based at least in part on a percentage of a capacity of the formed battery cell. In the method, the formation protocol can comprise charging or discharging one or more times at fixed or varying states of charge.

In the method, the first group of current-voltage signals can be processed to calculate a cell internal resistance of the formed battery cell. In the method, the first group of current-voltage signals can comprise one or more direct current charge or discharge pulses for up to 1 minute. The charge or discharge pulses can be obtained at states-of-charge less than or equal to 15%. The first group of current-voltage signals can comprise alternating current measurements. The alternating current resistance measurements can be obtained at states-of-charge less than or equal to 15%. The first group of current-voltage signals can comprise a measurement of voltage decay during rest, differential voltage, measurements including cell expansion and contraction, and acoustic response.

In the method, the second group of current-voltage signals can be measured after a battery capacity of the formed battery cell has decreased to below 80% of an initial capacity of the formed battery cell. The second group of current-voltage signals can be processed to calculate a measured capacity. The second group of current-voltage signals can be processed to calculate a measured cell internal resistance. The second group of current-voltage signals can comprise a measurement of voltage decay during rest, differential voltage, measurements including cell expansion and contraction, and acoustic response.

In the method, the statistical model can comprise a correlation. In the method, the statistical model can comprise a regression model. In the method, the optimized battery formation protocol can provide an optimized cycle life for the another battery cell. In the method, the optimized battery formation protocol can be determined by comparing resistances measured at states-of-charge less than or equal to 15%.

In the method, the cations can be lithium cations. The anode can comprise an anode material selected from graphite, lithium titanium oxide, hard carbon, tin/cobalt alloys, silicon/carbon, or lithium metal. The electrolyte can comprises a liquid electrolyte including a lithium compound in an organic solvent, and the cathode can comprise a cathode active material selected from (i) lithium metal oxides wherein the metal is one or more aluminum, cobalt, iron, manganese, nickel and vanadium, (ii) lithium-containing phosphates having a general formula LiMPO₄ wherein M is one or more of cobalt, iron, manganese, and nickel, and (iii) materials having a formula LiNiₓMn_{y}Co_{z}O₂, wherein x+y+z=1 and x:y:z=1:1:1 (NMC 111), x:y:z=4:3:3 (NMC 433), x:y:z=5:2:2 (NMC 522), x:y:z=5:3:2 (NMC 532), x:y:z=6:2:2 (NMC 622), or x:y:z=8:1:1 (NMC 811). The anode can comprise graphite; the lithium compound can selected from LiPF₆, LiBF₄, LiClO₄, lithium bis(fluorosulfonyl)imide (LiFSI), LiN(CF₃SO₂)₂ (LiTFSI), and LiCF₃SO₃ (LiTf); the organic solvent can be selected from carbonate based solvents, ether based solvents, ionic liquids, and mixtures thereof, the carbonate based solvent can be selected from the group consisting of dimethyl carbonate, diethyl carbonate, ethyl methyl carbonate, dipropyl carbonate, methylpropyl carbonate, ethylpropyl carbonate, methylethyl carbonate, ethylene carbonate, propylene carbonate, and butylene carbonate, and mixtures thereof; and the ether based solvent can be selected from the group consisting of diethyl ether, dibutyl ether, monoglyme, diglyme, tetraglyme, 2-methyltetrahydrofuran, tetrahydrofuran, 1,3-dioxolane, 1,2-dimethoxyethane, and 1,4-dioxane and mixtures thereof.

In still another aspect, the present disclosure provides a method for determining the amount of lithium consumed during a battery formation protocol. The method comprises: (a) providing a battery cell structure comprising an anode, an electrolyte, and a cathode including cations that move from the cathode to the anode during charging; (b) performing a first charge of the battery cell structure using a predetermined battery formation protocol to create a formed battery cell; (c) measuring current-voltage signals during or immediately after the battery formation protocol; and (d) processing the current-voltage signals to calculate the amount of lithium consumed during the battery formation protocol.

In the method, the battery formation protocol can comprise a charging current based at least in part on a percentage of a capacity of the formed battery cell. In the method, the battery formation protocol can comprise charging or discharging one or more times at fixed or varying states of charge. In the method, the current-voltage signals can be processed to calculate a cell internal resistance of the formed battery cell. In the method, the current-voltage signals can comprise one or more direct current charge or discharge pulses for up to 1 minute. In the method, the charge or discharge pulses can be obtained at states-of-charge less than or equal to 15%. In the method, the current-voltage signals can comprise alternating current measurements. The alternating current resistance measurements can be obtained at states-of-charge less than or equal to 15%. The current-voltage signals can comprise a measurement of voltage decay during rest, differential voltage, measurements including cell expansion and contraction, and acoustic response.

In yet another aspect, the present disclosure provides a method for predicting cycle life of a battery. The method comprises: (a) providing a battery cell structure comprising an anode, an electrolyte, and a cathode including cations that move from the cathode to the anode during charging; (b) performing a first charge of the battery cell structure using a predetermined formation protocol to create a formed battery cell; (c) measuring a first group of current-voltage signals during or immediately after the formation protocol of the formed battery cell; (d) measuring a second group of current-voltage signals by cycling the formed battery cell to an end of life; (e) repeating steps (a) through (d) for one or more additional battery cell structures; and (f) creating a statistical model taking the first group of current-voltage signals and the second group of current-voltage signals of each of the formed battery cell and additional formed battery cells as input and providing a prediction of cycle life for another battery cell. Step (f) can further comprise creating the statistical model using one or more features selected from: (i) electrical data from the battery formation process, including voltage decay during rest, differential capacity, differential voltage, and (ii) measurements including cell expansion and contraction, and acoustic response.

In the method, the formation protocol can comprise a charging current based at least in part on a percentage of a capacity of the formed battery cell. In the method, the formation protocol can comprise charging or discharging one or more times at fixed or varying states of charge.

In the method, the first group of current-voltage signals can be processed to calculate a cell internal resistance of the formed battery cell. The first group of current-voltage signals can comprise one or more direct current charge or discharge pulses for up to 1 minute. The charge or discharge pulses can be obtained at states-of-charge less than or equal to 15%. The first group of current-voltage signals can comprise alternating current measurements. The alternating current resistance measurements can be obtained at states-of-charge less than or equal to 15%. The first group of current-voltage signals can comprise a measurement of voltage decay during rest, differential voltage, measurements including cell expansion and contraction, and acoustic response.

In the method, the second group of current-voltage signals can be measured after a battery capacity of the formed battery cell has decreased to below 80% of an initial capacity of the formed battery cell. The second group of current-voltage signals can be processed to calculate a measured capacity. The second group of current-voltage signals can be processed to calculate a measured cell internal resistance. The second group of current-voltage signals can comprise a measurement of voltage decay during rest, differential voltage, measurements including cell expansion and contraction, and acoustic response.

In the method, the statistical model can comprise a correlation. In the method, the statistical model can comprise a regression model.

It is an advantage of the invention to provide systems and methods to diagnose and predict battery lifetime using signals obtained from the battery manufacturing process. Multiple signals derived from current and voltage time series data are extracted from the battery manufacturing process. These signals are found to correlate to long term battery lifetime. Statistical models trained on these signals predict differences in battery lifetime caused by changes in manufacturing processes such as changes in the battery formation protocol. The signals are obtainable using already-existing battery manufacturing equipment. Thus, they require no additional equipment cost to implement and can be deployed at scale. The signals can be collected within hours following the completion of battery manufacturing, significantly reducing the time required for battery lifetime evaluation, which typically take months to complete.

In a particular embodiment, the signal comprises the cell internal resistance (R) measured at states of charge (SOCs) below 15% and using pulse durations less than 1 minute. The signals can also include the positive electrode capacity, the negative electrode capacity, and the lithium inventory, as estimated using feature extraction techniques such as differential capacity voltage fitting algorithms. The signals can further include the voltage decay during a rest step. These signals may be obtained directly from the battery formation process, or they may be obtained immediately following the battery formation process.

It is identified that R improves upon the signal-to-noise ratio of measuring the capacity lost due to lithium trapping in the solid electrolyte interphase (SEI) during battery formation. Differences in R are attributed to changes to the capacity of the SEI created during formation which can subsequently impact long-term battery lifetime. R is also sensitive to changes in the maximum cathode lithiation state. A decrease in R corresponds to a decrease in the maximum cathode lithiation state, which can protect the cathode against stress over life to improve battery lifetime. A decrease in R can also correspond to an increase in the cathode potential at the fully charged state, which can increase the rate of electrolyte oxidation and result in more gas generated at the end of life. It is further demonstrated that the magnitude of the R signal improves at lower SOCs and at earlier points in life. As battery systems improve their first cycle loss, the magnitude of R measurable at the beginning of life also increases, further improving the signal to noise ratio. This makes R an ideal signal for early life battery diagnostics for new battery systems.

The systems and methods herein can in principle also be extended to evaluate battery manufacturing processes beyond battery formation. For example, any manufacturing process change that can introduce changes to the SEI formation process could, in theory, be detected by R. These changes include, but are not limited to, changes in the electrolyte composition, electrode calendaring conditions, electrolyte filling amount, electrode drying conditions, and electrode mixing conditions.

These and other features, aspects, and advantages of the present invention will become better understood upon consideration of the following detailed description, drawings and appended claims.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is a schematic of a lithium ion battery.

FIG. 1A is a schematic of a lithium metal battery.

FIG. 1B shows a graphical abstract of one example embodiment of the present invention.

FIG. 2 shows cycle life test results, wherein (a,c) show discharge capacity for individual cells measured during the 1 C/1 C aging test at (a) room temperature and (c) 45° C. wherein gaps in the curves correspond to the embedded reference performance test (RPT) cycles; and wherein (b,d) show end-of-life capacity retention distributions, defined as when the cell discharge capacity reaches 70% of initial capacity (wherein ***=statistically significant with p-value <0.001).

FIG. 3 shows diagnostic signals for differences in the initial cell state, wherein (a-c) show diagnostic signals obtained during formation for all cells; and wherein (d-f) show the 10-second resistance metric (R₁₀ₛ) obtained from Hybrid Pulse Power Characterization at the beginning of the 45° C. cycle life test (wherein *=statistically significant with p-value <0.05, and ***=statistically significant with p-value <0.001).

FIG. 4 shows correlation between early life diagnostic signals and cycle life' wherein (a-d) show correlations under room temperature cycling, (e-h) show correlations under 45° C. cycling wherein cycle life is defined as cycles to 70% of initial capacity. Q_{LLI} and CE_{f} are taken directly from the formation test. R_{10s;5%SOC} and R_{10s;5%SOC} are measured at the beginning of the cycle life test and thus share the same temperature as the cycle life test.

FIG. 5 shows a toy model showing the impact of fast formation on the initial cell state wherein (a,b) show relative alignment of the cathode and anode equilibrium potential curves after baseline formation (a) and fast formation (b); (c,d) show corresponding cell resistances, where the measured full cell resistances (black lines) have been broken down into two categories: cathode charge transfer resistance and all other resistances wherein dashed lines denote the impact of fast formation on the relative alignment of the equilibrium potential curves (b) as well as the resistance curves (d).

FIG. 6 shows the connection between fast formation degradation pathway and the R_{10s;5%SOC} early life diagnostic signal.

FIG. 7 shows a pouch cell swelling at the end of the cycle life test, wherein (a) shows example images of pouch cells taken after aging showing varying degrees of swelling; wherein (b-c) show comparison of pouch cell thicknesses measured at the end of the cycle life test, wherein (b) shows cells cycled at room temperature, wherein (c) shows cells cycled at 45° C. (wherein ***=statistically significant with p-value <0.001, and wherein ‘n.s.’ means not statistically significant).

FIG. 8 shows aging variability as a function of end-of-life definition, wherein (a,b) show cycles to end of life under room temperature (a) and 45° C. cycling, wherein boxes show inter-quartile range (IQR) and whiskers show the min and max values, wherein (c,d) show inter-quartile range (IQR) divided by median plotted as a function of end of life capacity definition for room temperature (a) and 45° C. (d) cycling.

FIG. 9 shows the experimental design for the study in the Example below, wherein (a) shows distribution of cells across two formation protocols and two aging temperatures, wherein the aging test consists of 1 C charge/discharge cycles between 3.0V and 4.2V, with reference performance tests (RPTs) inserted periodically into the test, wherein (b, c) show voltage and current vs. time profiles for (b) fast formation and (c) baseline formation.

FIG. 10 shows mean capacity-weighted discharge voltage over cycle number.

FIG. 11 shows coulombic efficiency over cycle number.

FIG. 12 shows voltage efficiency over cycle number.

FIG. 13 shows discharge energy over cycle number.

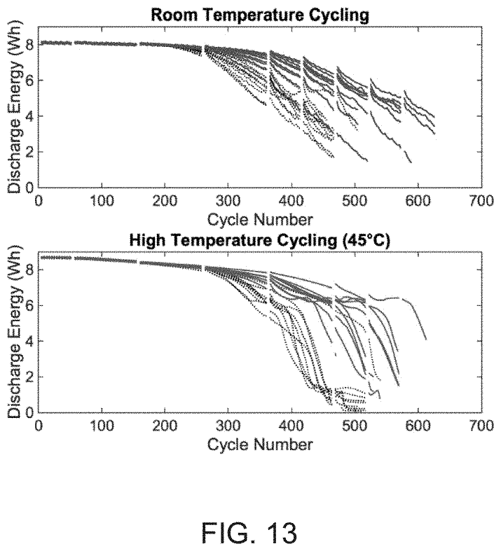

FIG. 14 shows an example of the usage of hybrid power pulse characterization (HPPC) for extracting the 10-second discharge resistance across different SOCs, wherein the HPPC pulses are included as part of every reference performance test (RPT).

FIG. 15 shows initial distribution of direct-current resistance (DCR) at both temperatures.

FIG. 16 shows the effect of SOC on the cell resistance measured from HPPC.

FIG. 17 shows the effect of pulse duration on the cell resistance measured from HPPC.

FIG. 18 shows the correlation between R_{10s;5%SOC} and conventional metrics of lithium consumption during formation, wherein (a,b) show correlation with R_{10s;5%SOC} measured at room temperature, wherein (c,d) show correlation with R_{10s;5%SOC} measured at 45° C., wherein in all cases, Q_{LLI}=Q_{c}−Q_{d} and CE_{f} are both measured at room temperature.

FIG. 19 shows the correlation between initial cell state signals and various end of life definitions for room temperature cycling, wherein formation signals (Q_{LLI} and CE_{f}) are always measured at room temperature, wherein R_{10s;5%SOC} and R_{10s;5%SOC} are measured at the same temperature as the cycle life test.

FIG. 20 shows the correlation between initial cell state signals and various end of life definitions for 45° cycling, wherein formation signals (Q_{LLI} and CE_{f}) are always measured at room temperature, wherein R_{10s;5%SOC} and R_{10s;5%SOC} are measured at the same temperature as the cycle life test.

FIG. 21 shows initial cell voltage curves before formation.

FIG. 22 shows a toy model showing impact of fast formation on the initial cell state, wherein in this plot, ΔQ_{LLI}=23 mAh.

FIG. 23 shows images of pouch cells taken after aging showing varying degrees of swelling, wherein cell #9 has been excluded from the study of the Example below due to tab weld issues.

FIG. 24 shows temperature measurement during cycle life testing, wherein (a,b) show time-series data for the room temperature (a) and 45° C. (b) tests, wherein (c,d) show temperature histograms for the room temperature (a) and 45° C. (d) tests.

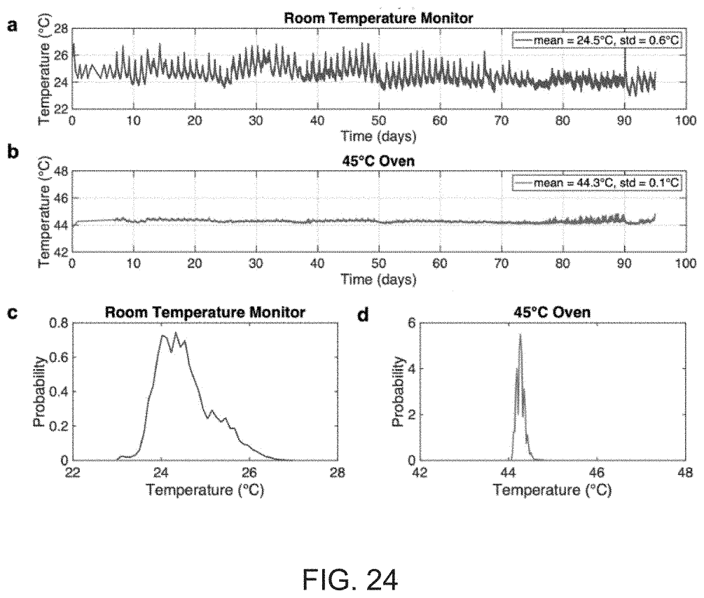

FIG. 25 shows the pouch cell architecture used for all cells in the study of the Example below, wherein the left view is a side view of stack definition, and wherein the right view is a side view of unit cell definition.

### DETAILED DESCRIPTION OF THE INVENTION

Before any embodiments of the invention are explained in detail, it is to be understood that the invention is not limited in its application to the details of construction and the arrangement of components set forth in the following description or illustrated in the following drawings. The invention is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items.

The following discussion is presented to enable a person skilled in the art to make and use embodiments of the invention. Various modifications to the illustrated embodiments will be readily apparent to those skilled in the art, and the generic principles herein can be applied to other embodiments and applications without departing from embodiments of the invention. Thus, embodiments of the invention are not intended to be limited to embodiments shown, but are to be accorded the widest scope consistent with the principles and features disclosed herein. Skilled artisans will recognize the examples provided herein have many useful alternatives and fall within the scope of embodiments of the invention.

As used herein, the battery state of charge (SOC) gives the ratio of the amount of energy presently stored in the battery to the nominal rated capacity of the battery expressed as a percentage or a number in the range of 0 to 1. For example, for a battery with a 1 amp hours (Ah) capacity and having an energy stored in the battery of 0.8 Ah, the SOC is 80% or 0.8. SOC can also be expressed as a unit, such as 0.8 Ah for a battery with a 1 Ah capacity and having an energy stored in the battery of 0.8 Ah.

As used herein, the term “C-rate” can be understood as follows. Charge and discharge rates of a battery are governed by C-rates. The capacity of a battery is commonly rated at 1 C, meaning that a fully charged battery rated at 1 Ah should provide 1 amp (A) for one hour. The same battery discharging at 0.5 C should provide 0.5 A for two hours, and at 2 C, it delivers 2 A for 30 minutes. As illustrative examples, a C-rate of 1 C is also known as a one-hour charge or discharge; a C-rate of 4 C is a ¼-hour charge or discharge; a C-rate of 2 C is a ½-hour charge or discharge; a C-rate of 0.5 C or C/2 is a 2-hour charge or discharge; a C-rate of 0.2 C or C/5 is a 5-hour charge or discharge, and a C-rate of 0.1 C or C/10 is a 10-hour charge or discharge.

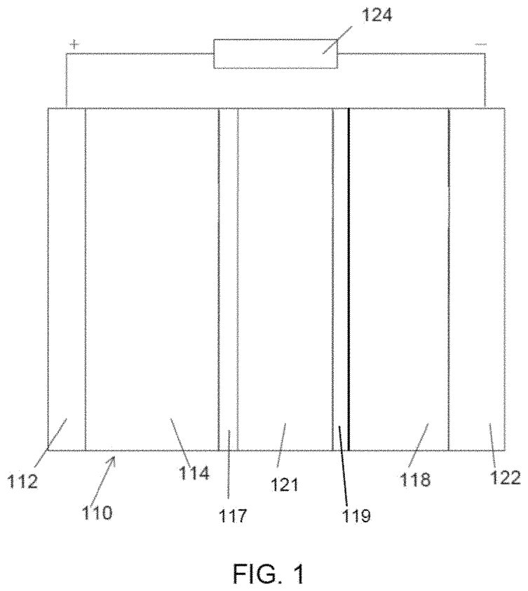

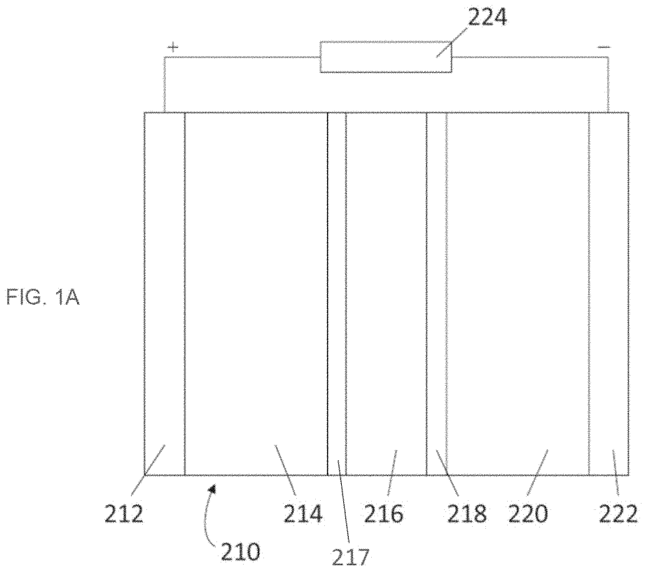

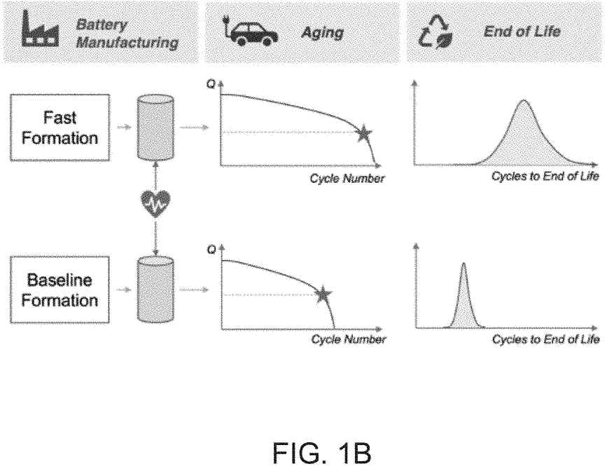

FIG. 1 shows a non-limiting example of a lithium ion battery 110 that may be manufactured according to one embodiment of the present disclosure. The lithium ion battery 110 includes a first current collector 112 (e.g., aluminum) in contact with a cathode 114. A solid state electrolyte 121 is arranged between a solid electrolyte interphase 117 on the cathode 114 and a solid electrolyte interphase 119 on an anode 118, which is in contact with a second current collector 122 (e.g., aluminum). The first and second current collectors 112 and 122 of the lithium ion battery 110 may be in electrical communication with an electrical component 124. The electrical component 124 could place the lithium ion battery 110 in electrical communication with an electrical load that discharges the battery or a charger that charges the battery.

A suitable active material for the cathode 114 of the lithium ion battery 110 is a lithium host material capable of storing and subsequently releasing lithium ions. An example cathode active material is a lithium metal oxide wherein the metal is one or more aluminum, cobalt, iron, manganese, nickel and vanadium. Non-limiting example lithium metal oxides are LiCoO₂ (LCO), LiFeO₂, LiMnO₂ (LMO), LiMn₂O₄, LiNiO₂ (LNO), LiNiₓCo_{y}O₂, LiMnₓCo_{y}O₂, LiMnₓNi_{y}O₂, LiMnₓNi_{y}O₄, LiNiₓCo_{y}Al_{z}O₂ (NCA), LiNi_{1/3}Mn_{1/3}Co_{1/3}O₂ and others. Another example of cathode active materials is a lithium-containing phosphate having a general formula LiMPO₄ wherein M is one or more of cobalt, iron, manganese, and nickel, such as lithium iron phosphate (LFP) and lithium iron fluorophosphates. The cathode can comprise a cathode active material having a formula LiNiₓMn_{y}Co_{z}O₂, wherein x+y+z=1 and x:y:z=1:1:1 (NMC 111), x:y:z=4:3:3 (NMC 433), x:y:z=5:2:2 (NMC 522), x:y:z=5:3:2 (NMC 532), x:y:z=6:2:2 (NMC 622), or x:y:z=8:1:1 (NMC 811). The cathode active material can be a mixture of any number of these cathode active materials.

In some aspects, the cathode 114 may include a conductive additive. Many different conductive additives, e.g., Co, Mn, Ni, Cr, Al, or Li, may be substituted or additionally added into the structure to influence electronic conductivity, ordering of the layer, stability on delithiation and cycling performance of the cathode materials. Other suitable conductive additives include graphite, carbon black, acetylene black, Ketjen black, channel black, furnace black, lamp black, thermal black, conductive fibers, metallic powders, conductive whiskers, conductive metal oxides, and mixtures thereof.

A suitable active material for the anode 118 of the lithium ion battery 110 is a lithium host material capable of incorporating and subsequently releasing the lithium ion such as graphite (artificial, natural), a lithium metal oxide (e.g., lithium titanium oxide), hard carbon, a tin/cobalt alloy, or silicon/carbon. The anode active material can be a mixture of any number of these anode active materials. In some embodiments, the anode 118 may also include one or more conductive additives similar to those listed above for the cathode 114.

A suitable solid state electrolyte 121 of the lithium ion battery 110 includes an electrolyte material having the formula LiᵤReᵥM_{w}AₓO_{y}, wherein

Re can be any combination of elements with a nominal valance of +3 including La, Nd, Pr, Pm, Sm, Sc, Eu, Gd, Tb, Dy, Y, Ho, Er, Tm, Yb, and Lu;

M can be any combination of metals with a nominal valance of +3, +4, +5 or +6 including Zr, Ta, Nb, Sb, W, Hf, Sn, Ti, V, Bi, Ge, and Si;

A can be any combination of dopant atoms with nominal valance of +1, +2, +3 or +4 including H, Na, K, Rb, Cs, Ba, Sr, Ca, Mg, Fe, Co, Ni, Cu, Zn, Ga, Al, B, and Mn;

u can vary from 3-7.5;

v can vary from 0-3;

w can vary from 0-2;

x can vary from 0-2; and

y can vary from 11-12.5.

The electrolyte material may be a lithium lanthanum zirconium oxide. The electrolyte material may have the formula Li_{6.25}La_{2.7}Zr₂Al_{0.25}O₁₂.

Another example solid state electrolyte 121 can include any combination oxide or phosphate materials with a garnet, perovskite, NaSICON, or LiSICON phase. The solid state electrolyte 121 of the lithium ion battery 110 can include any solid-like material capable of storing and transporting ions between the anode 118 and the cathode 114.

The current collector 112 and the current collector 122 can comprise a conductive material. For example, the current collector 112 and the current collector 122 may comprise molybdenum, aluminum, nickel, copper, combinations and alloys thereof or stainless steel.

Alternatively, a separator may replace the solid state electrolyte 121, and the electrolyte for the battery 110 may be a liquid electrolyte. An example separator material for the battery 110 can a permeable polymer such as a polyolefin. Example polyolefins include polyethylene, polypropylene, and combinations thereof. The liquid electrolyte may comprise a lithium compound in an organic solvent. The lithium compound may be selected from LiPF₆, LiBF₄, LiClO₄, lithium bis(fluorosulfonyl)imide (LiFSI), LiN(CF₃SO₂)₂ (LiTFSI), and LiCF₃SO₃ (LiTf). The organic solvent may be selected from carbonate based solvents, ether based solvents, ionic liquids, and mixtures thereof. The carbonate based solvent may be selected from the group consisting of dimethyl carbonate, diethyl carbonate, ethyl methyl carbonate, dipropyl carbonate, methylpropyl carbonate, ethylpropyl carbonate, methylethyl carbonate, ethylene carbonate, propylene carbonate, and butylene carbonate; and the ether based solvent is selected from the group consisting of diethyl ether, dibutyl ether, monoglyme, diglyme, tetraglyme, 2-methyltetrahydrofuran, tetrahydrofuran, 1,3-dioxolane, 1,2-dimethoxyethane, and 1,4-dioxane.

The solid electrolyte interphases 117, 119 form during a first charge of the lithium ion battery 110. To further describe the formation of a solid electrolyte interphase, a non-limiting example lithium ion battery 110 using a liquid electrolyte and having an anode comprising graphite is used in this paragraph. As lithiated carbons are not stable in air, the non-limiting example lithium ion battery 110 is assembled in its discharged state that means with a graphite anode and lithiated positive cathode materials. The electrolyte solution is thermodynamically unstable at low and very high potentials vs. Li/Li⁺. Therefore, on first charge of the lithium ion battery cell, the electrolyte solution begins to reduce/degrade on the graphite anode surface and forms the solid electrolyte interphase (SEI). There are competing and parallel solvent and salt reduction processes, which result in deposition of a number of organic and inorganic decomposition products on the surface of the graphite anode. The SEI layer imparts kinetic stability to the electrolyte against further reductions in the successive cycles and thereby ensures good cyclability of the electrode. It has been reported that SEI thickness may vary from few angstroms to tens or hundreds of angstroms. Studies suggest the SEI on a graphitic anode to be a dense layer of inorganic components close to the carbon of the anode, followed by a porous organic or polymeric layer close to the electrolyte phase.

The present invention is not limited to lithium ion batteries. In alternative embodiments, a suitable anode can comprise magnesium, sodium, or zinc. Suitable alternative cathode and electrolyte materials can be selected for such magnesium ion batteries, sodium ion batteries, or zinc ion batteries. For example, a sodium ion battery can include: (i) an anode comprising sodium ions, (ii) a solid state electrolyte comprising a metal cation-alumina (e.g., sodium-β-alumina or sodium-β″-alumina), and (iii) a cathode comprising an active material selected from the group consisting of layered metal oxides, (e.g., NaFeO, NaMnO, NaTiO, NaNiO, NaCrO, NaCoO, and NaVO) metal halides, polyanionic compounds, porous carbon, and sulfur containing materials.

FIG. 1A shows a non-limiting example of a lithium metal battery 210 that may be manufactured according to one embodiment of the present disclosure. The lithium metal battery 210 includes a current collector 212 in contact with a cathode 214. A solid state electrolyte 216 is arranged between a solid electrolyte interphase 217 on the cathode 214 and a solid electrolyte interphase 218 on an anode 220, which is in contact with a second current collector 222 (e.g., aluminum). The current collectors 212 and 222 of the lithium metal battery 210 may be in electrical communication with an electrical component 224. The electrical component 224 could place the lithium metal battery 210 in electrical communication with an electrical load that discharges the battery or a charger that charges the battery. A suitable active material for the cathode 214 of the lithium metal battery 210 is one or more of the lithium host materials listed above for battery 110, or porous carbon (for a lithium air battery), or a sulfur containing material (for a lithium sulfur battery). A suitable solid state electrolyte material for the solid state electrolyte 216 of the lithium metal battery 210 is one or more of the solid state electrolyte materials listed above for battery 110. In one embodiment, the anode 220 of the lithium metal battery 210 comprises lithium metal. In one embodiment, the anode 220 of the lithium metal battery 210 consists essentially of lithium metal.

Alternatively, a separator may replace the solid state electrolyte 216, and the electrolyte for the lithium metal battery 210 may be a liquid electrolyte. An example separator material for the lithium metal battery 210 is one or more of the separator materials listed above for lithium ion battery 110. A suitable liquid electrolyte for the lithium metal battery 210 is one or more of the liquid electrolytes listed above for lithium ion battery 110.

The solid electrolyte interphases 217, 218 form during a first charge of the lithium metal battery 210. To further describe the formation of a solid electrolyte interphase, a non-limiting example lithium metal battery 210 using a liquid electrolyte and having a lithium metal anode is used in this paragraph. The liquid electrolyte comprises a lithium salt in an organic solvent. The non-limiting example lithium metal battery 210 is assembled in its discharged state which means with a lithium metal anode and lithiated positive cathode materials. The reduction potential of the organic solvent is typically below 1.0 V (vs. Li⁺/Li). Therefore, when the bare lithium anode is exposed to the electrolyte solution and a first charging current is applied, immediate reactions between lithium and electrolyte species are carried out. The insoluble products of the parasitic reactions between lithium ions, anions, and solvents depositing on the metallic lithium anode surface are regarded as the solid electrolyte interphase. As the SEI components strongly depend on the electrode material, electrolyte salts, solvents, as well as the working state of cell, no identical SEI layer can be found in two different situations. Consequently, the actual surface chemistry of SEI layer in a given system is typically obtained by characterization methods such as Fourier transform infrared spectroscopy (FTIR) and X-ray photoelectron spectroscopy (XPS).

The present invention is not limited to lithium metal batteries. In alternative embodiments, a suitable anode can comprise magnesium metal, sodium metal, or zinc metal. Suitable alternative cathode and electrolyte materials can be selected for such magnesium metal batteries, sodium metal batteries, or zinc metal batteries.

In one embodiment of the invention, there is provided a method for forming a battery. First, a battery cell structure is assembled in a discharged state that comprises an anode, an electrolyte, and a cathode including cations that move from the cathode to the anode during charging. For example, any of the metal ion batteries or metal batteries described above can be assembled in a discharged state using any of the non-limiting example anode materials, electrolyte material, and cathode materials described above. In the non-limiting example case of a lithium ion battery or a lithium metal battery, lithiated cathode materials are used. A first charge of the battery cell structure is then performed using a predetermined formation protocol to create a formed battery cell.

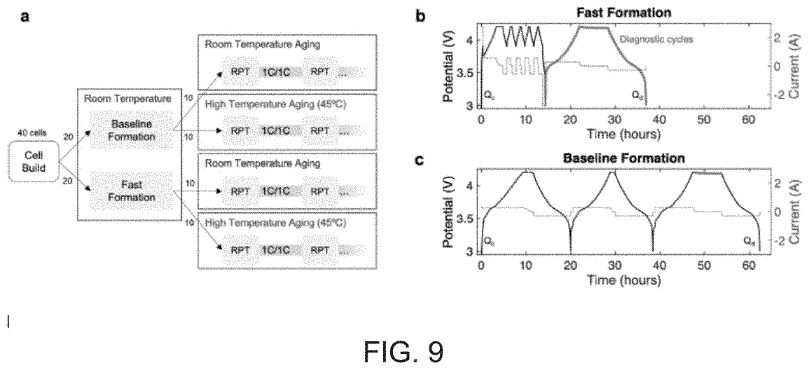

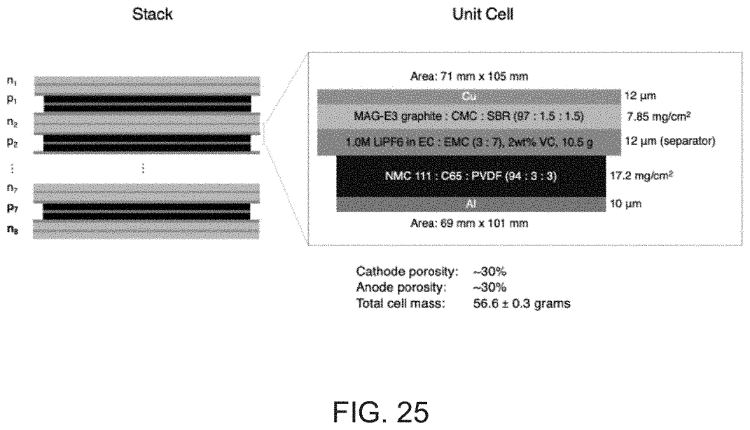

Numerous formation protocols can be used, and the formation protocols can include charging and discharging currents based on the battery cell capacity C. Various charging and discharging and rest time periods can be used, and the charging voltage(s) and discharging cutoff voltage(s) can be selected based on, among other things, the battery chemistry. In the non-limiting example formation protocol shown in panel b of FIG. 9, a battery cell structure as shown in FIG. 25 is brought to 3.9V using a 1 C (2.36 Ah) charge, followed by five consecutive charge-discharge cycles between 3.9V and 4.2V at C/5, and finally ending on a 1 C discharge to 2.5V. Each charge step terminates on a CV hold until the current falls below C/100. A C/10 charge and C/10 discharge cycle was appended at the end of the test to measure the post-formation cell discharge capacity. A 6-hour step was included in between the C/10 charge-discharge steps to monitor the voltage decay. The formation sequence takes 14 hours to complete after excluding time taken for diagnostic steps. In the non-limiting example formation protocol shown in panel c of FIG. 9, a battery cell structure as shown in FIG. 25 is subjected to a formation protocol that comprises three consecutive C/10 charge-discharge cycles between 3.0V and 4.2V. A 6-hour rest was also added between the final C/10 charge-discharge step to monitor the voltage decay signal. The total formation time amounts to 50 hours after excluding the diagnostic steps.

In this embodiment of the invention, the predetermined formation protocol can be determined by: (i) determining a first cell internal resistance of a first reference battery cell formed by using a first cell structure identical to the battery cell structure and performing a first initial charge of the first cell structure using a first formation protocol, (ii) determining a second cell internal resistance of a second reference battery cell formed by using a second cell structure identical to the battery cell structure and performing a second initial charge of the second cell structure using a second formation protocol, wherein the second formation protocol is different from the first formation protocol, and (iii) selecting the predetermined formation protocol to correspond to the first formation protocol if the first cell internal resistance is greater than or less than the second cell internal resistance, and selecting the predetermined formation protocol to correspond to the second formation protocol if the second cell internal resistance is greater than or less than the first cell internal resistance. In this regard, it has been determined that a lower cell internal resistance correlates with a higher cycle life of the formed battery cell. Therefore, when comparing two formation protocols, one selects the formation protocol that has the highest predicted cycle life, which is correlated to the lower cell internal resistance as demonstrated in the present disclosure. Alternatively, in certain battery chemistries, a higher cell internal resistance may correlate with a higher cycle life of the formed battery cell. While a comparison requires performing at least two different formation protocols, it should be understood that the invention can be used to compare any number of formation protocols greater than two.

Various features of this embodiment of the invention provide particular advantages. For example, it is beneficial that the cell internal resistance be determined when the state of charge of a battery cell is 15% or lower as it has been demonstrated in the present disclosure that differences in cell internal resistance between the two formation protocols uniquely appear at low state of charge (SOC) values. Without intending to be bound by theory, the low-SOC resistance is mainly a reflection of the cathode charge transfer. Determining cell internal resistance when the state of charge of a battery cell is 10% or lower is even more beneficial, and determining cell internal resistance when the state of charge of a battery cell is 5% or lower is also beneficial. The cell internal resistances of the battery cells can determined using a series of discharge pulses, wherein the discharge pulses have a pulse duration less than 1 minute. The cell internal resistances of the battery cells can determined after various numbers of charges of the cell. It is beneficial that the cell internal resistance of a battery cell is determined before a second charge of the battery cell.

In one version of this embodiment of the invention, the cations that move from the cathode to the anode during charging (and move from the anode to the cathode during discharging) are lithium cations, e.g., the battery can be a lithium ion battery (such as lithium ion battery 110) or a lithium metal battery (such as lithium metal battery 210). In a non-limiting example lithium ion battery or a non-limiting example lithium metal battery, various formation processes can be used. The battery manufacturing process can change the amount of lithium consumed during formation, e.g., different electrolytes and electrolyte additives, different cathode and anode active materials, different electrode designs (e.g., cathode porosities and anode porosities of 10% to 50%, or 20% to 40%, or 25% to 35%), different calendaring processes (which affect electrode porosities). This embodiment of the invention is particularly advantageous in lithium ion battery systems but is beneficial in any battery system that has solid electrolyte interphase (SEI) formation process, including lithium metal, solid state, sodium ion.

In another embodiment of the invention, there is provided a method for predicting cycle life of a battery. First, a first battery cell structure is assembled in a discharged state that comprises an anode, an electrolyte, and a cathode including cations that move from the cathode to the anode during charging. For example, any of the metal ion batteries or metal batteries described above can be assembled in a discharged state using any of the non-limiting example anode materials, electrolyte material, and cathode materials described above. In the non-limiting example case of a lithium ion battery or a lithium metal battery, lithiated cathode materials are used. Then, a first charge of the battery cell structure is performed using a predetermined formation protocol to create a formed battery cell. A cell internal resistance of the formed battery cell is then determined. As noted above, it has been determined that the lower cell internal resistance correlates with the higher cycle life of the formed battery cell. Alternatively, in certain battery chemistries, a higher cell internal resistance may correlate with a higher cycle life of the formed battery cell.

The cell internal resistance of a plurality of formed battery cells can be determined. Characteristic curves (which may include linear and/or non-linear relationships) can be created of measured or modelled predicted cycle life versus cell internal resistance of reference battery cells formed by using cell structures identical to the first battery cell structure and reference formation protocols different from the predetermined formation protocol. The characteristic curves for different formation protocols may be created by battery manufacturers in order to provide a means to calculate the predicted cycle life based on the cell internal resistance. A data storage device can be used to store these characteristic curves based on the cell internal resistance of different formed battery cells.

In this embodiment of the invention, one can compare the measured cell internal resistance of the formed battery cell to a characteristic curve of measured or model predicted cycle life versus cell internal resistance of reference battery cells formed by using cell structures identical to the battery cell structure and reference formation protocols different from the predetermined formation protocol to predict the cycle life of a battery.

Various features of this embodiment of the invention provide particular advantages. For example, it is beneficial that the cell internal resistance be determined when the state of charge of a battery cell is 15% or lower as it has been demonstrated in the present disclosure that differences in cell internal resistance between the two formation protocols uniquely appear at low state of charge (SOC) values. Without intending to be bound by theory, the low-SOC resistance is mainly a reflection of the cathode charge transfer. Determining cell internal resistance when the state of charge of a battery cell is 10% or lower is even more beneficial, and determining cell internal resistance when the state of charge of a battery cell is 5% or lower is also beneficial. The cell internal resistances of the battery cells can determined using a series of discharge pulses, wherein the discharge pulses have a pulse duration less than 1 minute. The cell internal resistances of the battery cells can determined after various numbers of charges of the cell. It is beneficial that the cell internal resistance of a battery cell is determined before a second charge of the battery cell.

In one version of this embodiment of the invention, the cations that move from the cathode to the anode during charging (and move from the anode to the cathode during discharging) are lithium cations, e.g., the battery can be a lithium ion battery (such as lithium ion battery 110) or a lithium metal battery (such as lithium metal battery 210). In a non-limiting example lithium ion battery or a non-limiting example lithium metal battery, various formation processes can be used. The battery manufacturing process can change the amount of lithium consumed during formation, e.g., different electrolytes and electrolyte additives, different cathode and anode active materials, different electrode designs (e.g., cathode porosities and anode porosities of 10% to 50%, or 20% to 40%, or 25% to 35%), different calendaring processes (which affect electrode porosities). This embodiment of the invention is particularly advantageous in lithium ion battery systems but is beneficial in any battery system that has solid electrolyte interphase (SEI) formation process, including lithium metal, solid state, sodium ion.

In yet another embodiment of the invention, there is provided a method for determining whether a first predicted cycle life of a first battery cell is greater than a second predicted cycle life of a second battery cell. First, a first battery cell structure is assembled in a discharged state that comprises an anode, an electrolyte, and a cathode including cations that move from the cathode to the anode during charging. For example, any of the metal ion batteries or metal batteries described above can be assembled in a discharged state using any of the non-limiting example anode materials, electrolyte material, and cathode materials described above. In the non-limiting example case of a lithium ion battery or a lithium metal battery, lithiated cathode materials are used. Then, a first initial charge of the first battery cell structure is performed using a predetermined formation protocol to create a first formed battery cell. A first cell internal resistance of the first formed battery cell is then determined. As noted above, it has been determined that a lower first cell internal resistance correlates with the higher cycle life of the first formed battery cell. Alternatively, in certain battery chemistries, a higher cell internal resistance may correlate with a higher cycle life of the formed battery cell.

Second, a second battery cell structure identical to the first battery cell structure is assembled in a discharged state that comprises an anode, an electrolyte, and a cathode including cations that move from the cathode to the anode during charging. For example, any of the metal ion batteries or metal batteries described above can be assembled in a discharged state using any of the non-limiting example anode materials, electrolyte material, and cathode materials described above. In the non-limiting example case of a lithium ion battery or a lithium metal battery, lithiated cathode materials are used. Then, a second initial charge of the second battery cell structure is performed using a predetermined formation protocol to create a second formed battery cell. A second cell internal resistance of the second formed battery cell is then determined. As noted above, it has been determined that a second cell internal resistance correlates with the cycle life of the second formed battery cell.

Third, one can determine that a first predicted cycle life of the first battery cell is greater than a second predicted cycle life of the second battery cell if the first cell internal resistance is lower than the second cell internal resistance. Alternatively, in certain battery chemistries, a higher cell internal resistance may correlate with a higher cycle life of the formed battery cell.

Various features of this embodiment of the invention provide particular advantages. For example, it is beneficial that the cell internal resistance be determined when the state of charge of a battery cell is 15% or lower as it has been demonstrated in the present disclosure that differences in cell internal resistance between the two formation protocols uniquely appear at low state of charge (SOC) values. Without intending to be bound by theory, the low-SOC resistance is mainly a reflection of the cathode charge transfer. Determining cell internal resistance when the state of charge of a battery cell is 10% or lower is even more beneficial, and determining cell internal resistance when the state of charge of a battery cell is 5% or lower is also beneficial. The cell internal resistances of the battery cells can determined using a series of discharge pulses, wherein the discharge pulses have a pulse duration less than 1 minute. The cell internal resistances of the battery cells can determined after various numbers of charges of the cell. It is beneficial that the cell internal resistance of a battery cell is determined before a second charge of the battery cell.

In one version of this embodiment of the invention, the cations that move from the cathode to the anode during charging (and move from the anode to the cathode during discharging) are lithium cations, e.g., the battery can be a lithium ion battery (such as lithium ion battery 110) or a lithium metal battery (such as lithium metal battery 210). In a non-limiting example lithium ion battery or a non-limiting example lithium metal battery, various formation processes can be used. The battery manufacturing process can change the amount of lithium consumed during formation, e.g., different electrolytes and electrolyte additives, different cathode and anode active materials, different electrode designs (e.g., cathode porosities and anode porosities of 10% to 50%, or 20% to 40%, or 25% to 35%), different calendaring processes (which affect electrode porosities). This embodiment of the invention is particularly advantageous in lithium ion battery systems but is beneficial in any battery system that has solid electrolyte interphase (SEI) formation process, including lithium metal, solid state, sodium ion.

In still another embodiment of the invention, there is provided a method for predicting cycle life of a battery. First, a battery cell structure is assembled in a discharged state that comprises an anode, an electrolyte, and a cathode including cations that move from the cathode to the anode during charging. For example, any of the metal ion batteries or metal batteries described above can be assembled in a discharged state using any of the non-limiting example anode materials, electrolyte material, and cathode materials described above. In the non-limiting example case of a lithium ion battery or a lithium metal battery, lithiated cathode materials are used. Then, a first initial charge of the battery cell structure is performed using a predetermined formation protocol to create a formed battery cell. A cell internal resistance is determined for the formed battery cell, and a cycle life of the formed battery cell is determined by cycling the formed battery cell to an end of life. One or more additional battery cell structures are assembled in a discharged state wherein the additional battery cell structures each comprises an anode, an electrolyte, and a cathode including cations that move from the cathode to the anode during charging. Then, a first initial charge of each of the additional battery cell structures is performed using a predetermined formation protocol to create a formed additional battery cell. The method can then include the steps of determining a cell internal resistance of each of the formed additional battery cells; and determining a cycle life of the formed additional battery cells by cycling the formed additional battery cells to an end of life. A statistical model is then trained by taking the cell internal resistance and cycle life of each of the formed battery cell and additional formed battery cells as input and providing a prediction of cycle life for another battery cell.

### Example

The following Example has been presented in order to further illustrate the invention and is not intended to limit the invention in any way. The statements provided in the Example are presented without being bound by theory.

### 1. Introduction to Example

In this Example, we show that the cell resistance at low states of charge can be used to improve the diagnostics and screening of new formation protocols. We demonstrate that the low-SOC resistance decreases as the quantity of lithium lost to the SEI during battery formation increases. This signal is shown to be a stronger predictor of battery lifetime compared to conventional signals such as the post-formation discharge capacity and coulombic efficiency. This metric can be measured within seconds and can be integrated directly into the battery manufacturing process at no additional costs. We believe that this low-SOC resistance metric can be deployed in practical manufacturing settings to accelerate the adoption of new formation protocols. Since this resistance metric reflects the amount of lithium consumed during formation, the metric can, in principle, also be used to diagnose the impact of any manufacturing process change that alters the total lithium consumed during formation.

Our design-of-experiments (shown in FIG. 9 at panel a) emphasizes larger samples sizes (n=10) compared those typically reported in literature, which often use three cells or fewer per group. The increased sample size enables a more statistically rigorous analysis of the impact of different formation protocols on cell characteristics at the beginning of life and at the end of life. Table 51 below provides cell design parameters for FIG. 9.

TABLE S1
Cell design parameters

| | Dimensions | 72 mm × 110 mm |
|---|---|---|
| | Stack (pos/neg) | 7/8 |
| Positive | Chemistry | NMC111 |
| | Composition | NMC111:C65:PVDF |
| | Ratio | 94:3:3 |

| | | |
|---|---|---|
| Loading (double-sided) | 34.45 | mg/cm² |
| Collector thickness | 12 | um |

| | | |
|---|---|---|
| Negative | Chemistry | Graphite |
| | Composition | MAG-E3:CMC:SBR |
| | Ratio | 97:1.5:1.5 |

| | | |
|---|---|---|
| Loading (double-sided) | 15.7 | mg/cm² |
| Collector thickness | 10 | um |

| | | |
|---|---|---|
| Electrolyte | Salt | 1.0M LiPF₆ |
| | Solvent | EC:EMC (3:7) |
| | Additive | 2 wt % VC, 4 g/Ah |

| | | |
|---|---|---|
| Mass | 10.55 | g |

| | | |
|---|---|---|
| Separator | Supplier | Entek |

| | | |
|---|---|---|
| Thickness | 12 | um |

Two formation protocols have been implemented in this Example: a fast formation protocol previously reported by Wood et al. [Ref. 15, 16] which completes within 14 hours (see FIG. 9 at panel b), as well as a baseline formation protocol (FIG. 9 at panel c) which completes in 60 hours. The fast formation protocol is designed to maximize the time spent at low anode potentials to promote the creation of a more passivating SEI [Ref. 15, 33-35].

For this Example, forty NMC/graphite pouch cells with a nominal capacity of 2.36 Ah were built. Half of the cells underwent fast formation and the remaining cells underwent baseline formation. For each formation type, cells were further subdivided into “room temperature” and “45° C.” aging groups to be cycled until their discharge capacities fell below 50% of the initial capacity. All cells were cycled under identical conditions: 1 C-1 C CCCV charge-discharge between 3.0V and 4.2V. Reference performance tests (RPTs) [Ref. 36] were inserted throughout the cycle life test, which includes slow (C/10) charge and discharge curves as well as a Hybrid Pulse Power Characterization (HPPC) sequence [Ref. 37] used to extract the cell internal resistance as a function of SOC.

### 2 Results and Discussion

### 2.1 Cycle Life Test

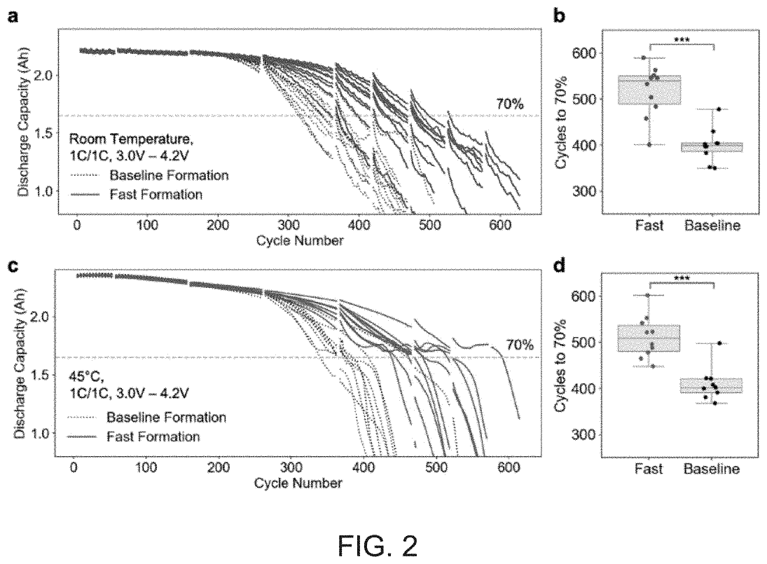

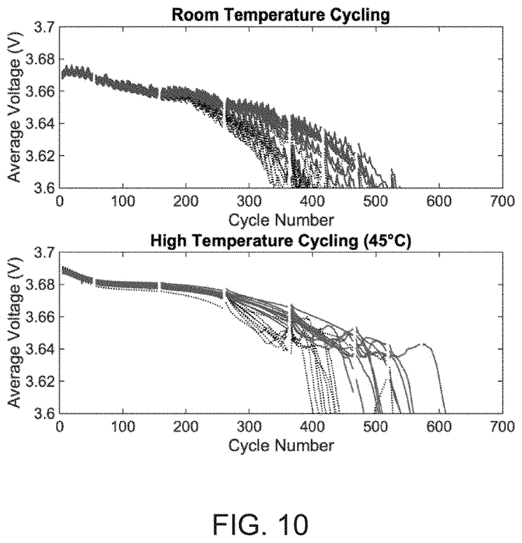

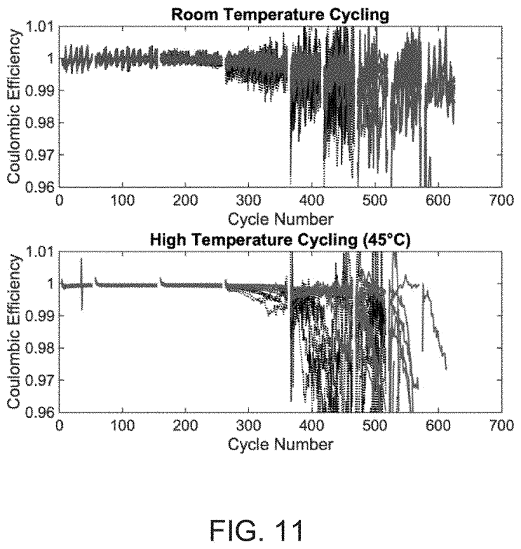

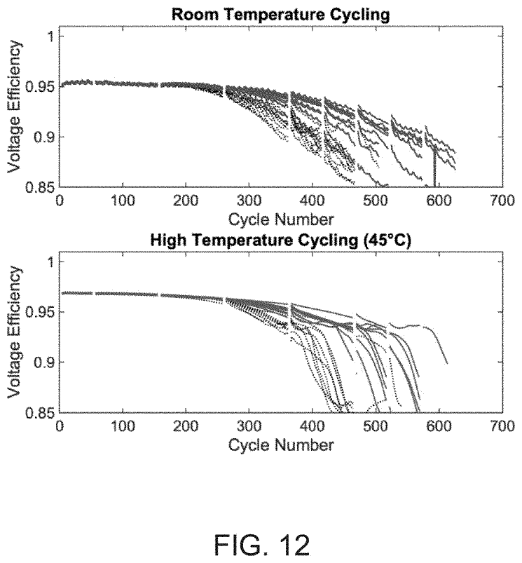

Fast formation cells lasted longer than the baseline formation cells under the cycle life test, as shown in FIG. 2. Panels (a) and (c) show that, under both temperatures tested, the degradation rate of fast formation cells initially track the baseline formation cells closely. However, after 250 cycles, all cells begin to lose capacity rapidly. Panels (b) and (d) show that the fast formation cells sustained over 100 cycles longer before reaching the end of life, defined as when cells reach 70% of the initial capacity. This result is highly statistically significant (p-value <0.001). The general result that fast formation improved cycle life performance holds across multiple performance metrics including average voltage (see FIG. 10), Coulombic efficiency (see FIG. 11), and voltage efficiency (see FIG. 12). Together, these results support the growing body of evidence that fast formation protocols can be designed to improve cycle life [Ref. 15, 22, 33].

### 2.2 Diagnostic Signals at the Beginning of Life

Given the clear impact of formation protocol on battery cycle life, we investigated methods to quantify the impact of fast formation on the initial cell state. Differences in the initial cell state may offer clues as to how fast formation could have improved cycle life. We focused our work on studying signals directly obtainable from full cell current-voltage data, which offer the lowest barrier-to-entry for deployment in real manufacturing settings.

### 2.2.1 Conventional Metrics of Formation Efficiency

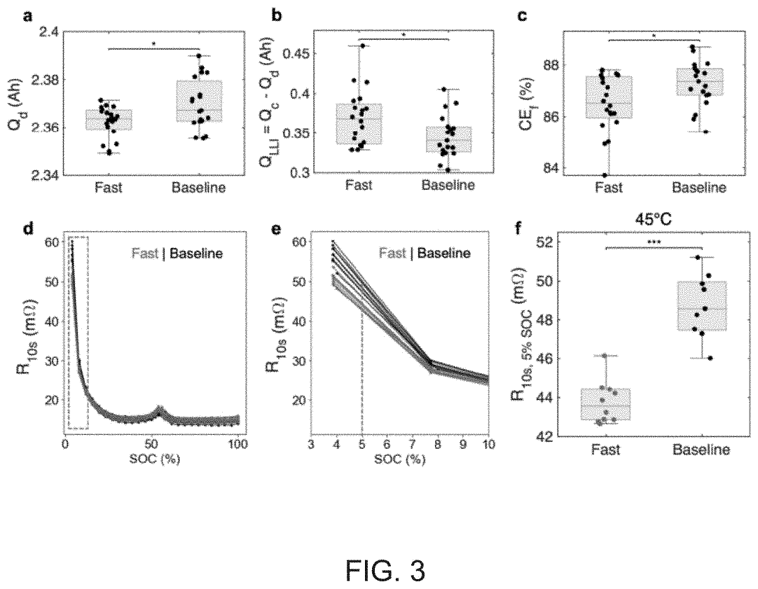

FIG. 3 in panels a-c show standard measures of formation efficiency extracted from the formation cycling data. The discharge capacity, Q_{d}, is measured at the end of each formation protocol during a C/10 discharge step from 4.2V to 3.0V. Q_{d} corresponds to the capacity of cyclable lithium excluding the lithium irreversibly lost to the SEI during formation. The charge capacity, Q_{c}, is taken during the initial charge cycle, and will include both the capacity of cyclable lithium as well as the capacity of lithium lost irreversibly to the SEI. Hence, the quantity of lithium inventory lost to the SEI can be calculated as Q_{LLI}=Q_{c}−Q_{d}. Note that while the two different formation protocols differed in the charging protocol, Q_{c} remains a fair comparison metric since both charge protocols ended on a potentiostatic hold at 4.2V until the current dropped below C/100. Finally, we also include another common evaluation metric, the formation coulombic efficiency, defined as CE_{f}=Q_{d}/Q_{c}, as shown in FIG. 3 panel c.

All measured values are summarized in Table 1 below. These results show that fast formation marginally increased the amount of lithium consumed during formation by 23 mAh. A p-value of less than 0.05 in all cases indicate that the measured differences, while small, are statistically significant.

TABLE 1
Comparison of initial cell state metrics. Values are reported as mean (standard
deviation). Q_{Δ}, Q_{LLI}, and CE [symbol] are extracted directly from the formation
test protocol. R₁₀ₛ metrics are extracted from the initial reference performance
test at the beginning of the cycle life test profile.

| | | | Fast | | Baseline | | | | |
|---|---|---|---|---|---|---|---|---|---|
| Metric | Unit | Temperature | Formation | | Formation | | Δ (abs) | Δ (%) | p-value |
| Q [symbol] | mAh | Room temp | 2362 | (7) | 2370 | (11) | −8 | −0.3% | 0.01 |
| Q_{LLI} = | mAh | Room temp | 369 | (35) | 346 | (27) | +23 | +6.6% | 0.03 |
| Q [symbol] − Q [symbol] | | | | | | | | | |
| CE [symbol] | [symbol] | Room temp | 86.5 | (1.1) | 87.3 | (0.9) | −0.8 | −0.9% | 0.02 |
| R [symbol] | mΩ | Room temp | 130.0 | (2.3) | 139.7 | (2.9) | −9.7 | −6.9% | <0.001 |
| R [symbol] | mΩ | 4 [symbol] ° C. | 43.8 | (1.1) | 48.7 | (1.6) | −4.9 | −10.0% | <0.001 |
| R [symbol] | mΩ | Room temp | 23.9 | (1.0) | 23.6 | (0.1) | +0.3 | +1.3% | 0.28 |
| R [symbol] | mΩ | 45° C. | 14.9 | (0.5) | 14.5 | (0.4) | +0.3 | +2.1% | 0.10 |

[symbol]

indicates data missing or illegible when filed

### 2.2.2 Low-SOC Resistance

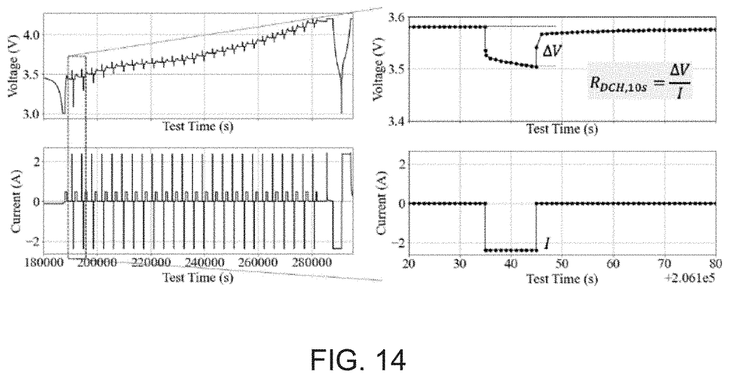

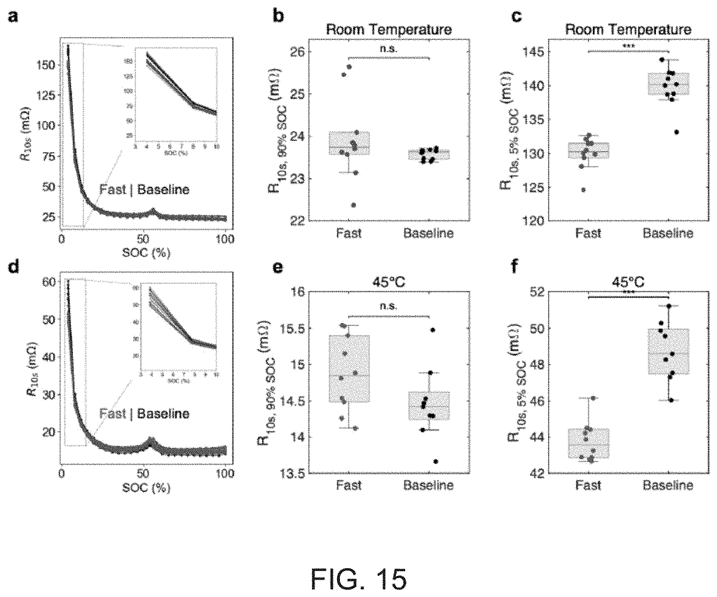

Following formation, the cell internal resistance was measured using the Hybrid Power Pulse Characterization (HPPC) technique [Ref. 37] prior to the start of the cycle life test. During this test, a series of 10-second discharge pulses are applied to the cell at varying SOCs and the resistance is calculated using Ohm's law (see FIG. 14). The 10-second resistance, R₁₀ₛ, is plotted against SOC for all cells cycled at 45° C. in FIG. 3 panel d. The cell resistance generally remains flat at mid-to high SOCs. The peak at approximately 55% SOC corresponds to the stage 2 solid-solution regime of the graphite anode [Ref. 38]. R₁₀ₛ rises sharply at SOCs below 10%. Focusing on the low-SOC region (see FIG. 3 panel e) reveals that, under fast formation, R₁₀ₛ measured at 4% and 8% SOC are lower than those of baseline formation cells. This result is highly statistically significant, with a p-value less than 0.001 (see FIG. 3 panel f). A similar result holds when R_{10s;5%SOC} is measured at room temperature (see FIG. 15). At mid to high SOCs, differences in Rios between fast formation and baseline formation cells are generally not statistically significant (see FIG. 15). Thus, differences in resistance between the two formation protocols uniquely appear at low SOCs. All initial cell state metrics are summarized as part of Table 1.

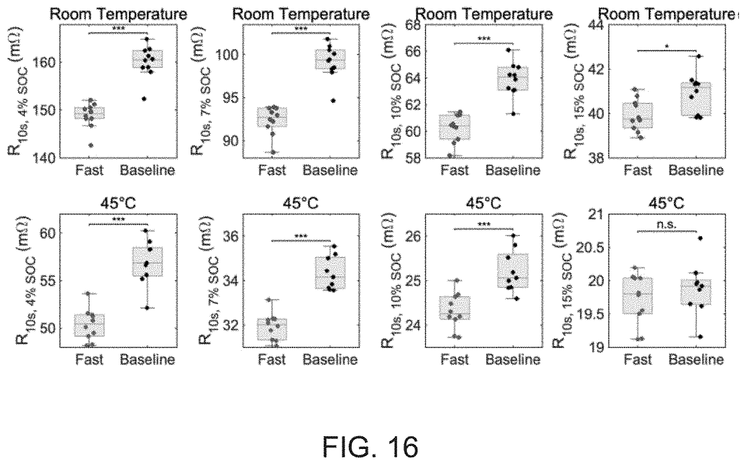

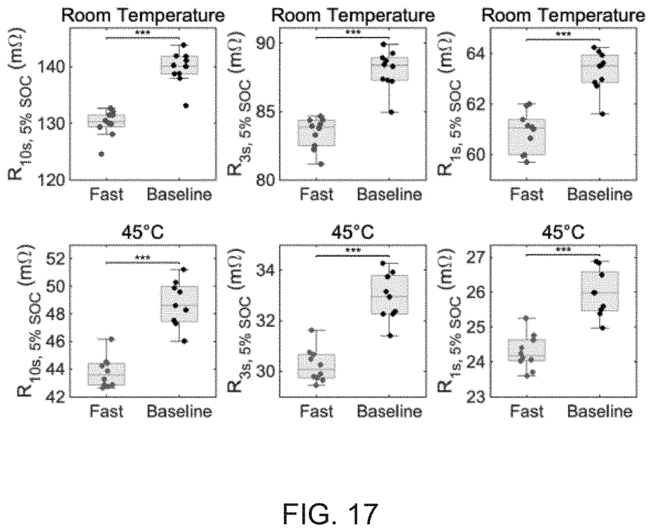

To study the robustness of the low SOC signal, we varied the SOC set-point between 4% and 10% and also computed the resistance under the 1-second and 5-second pulse durations. In all cases, the resistance metric provided a high degree of contrast between the two different formation protocols (see FIGS. 16 and 17). The lowest SOC tested in our dataset was 4% SOC. While obtaining data at even lower SOCs is possible, the cell may need to be temporarily over-discharged to below 3.0V to complete the full duration of the pulse. The remainder of this Example will focus on the resistance measured at 5% SOC and with a 10-second pulse duration. From here on, this metric will be referred to as R_{10s;5%SOC}.

### 2.3 Cycle Life Correlation and Prediction Using Low-SOC Resistance

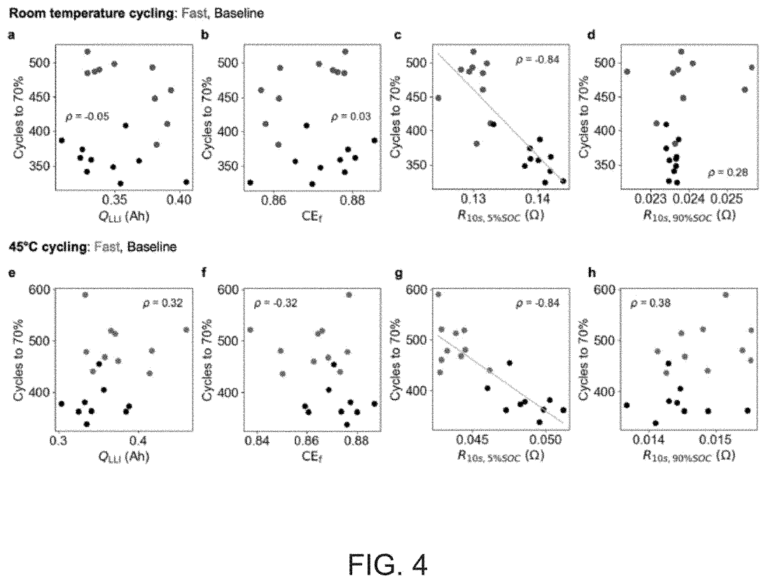

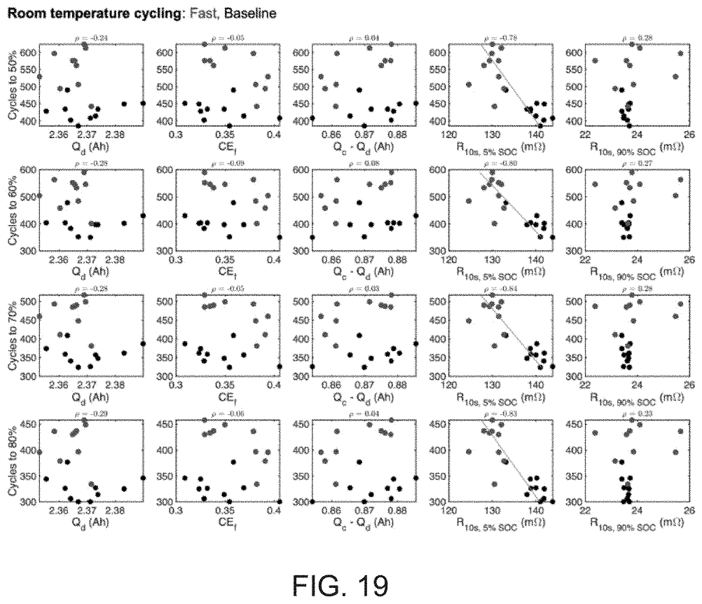

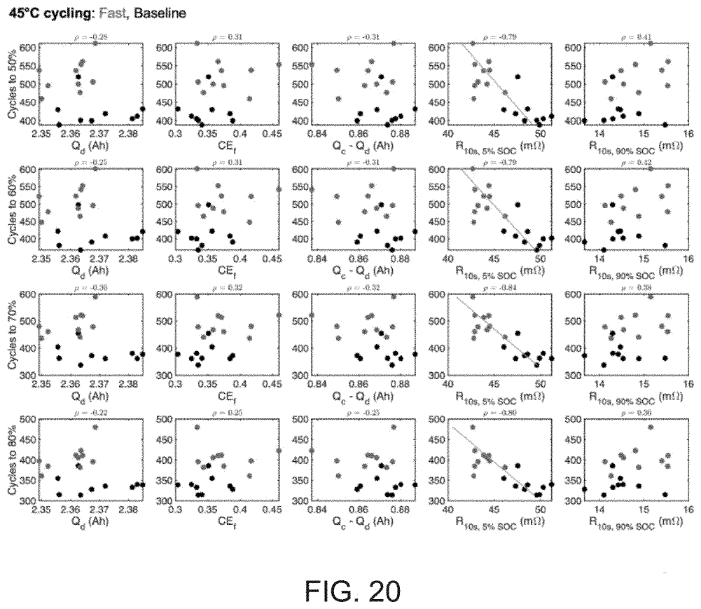

To evaluate the merit of R_{10s;5%SOC} as a diagnostic feature, we explored the correlations between the initial cell metrics introduced in FIG. 3 and the cycle life, defined as cycles to 70% of the initial capacity. The results are shown in FIG. 4. Out of all metrics studied, R_{10s;5%SOC} is the only signal with a meaningful correlation to cycle life, with a correlation coefficient of ρ=−0:84. By comparison, other metrics such as Q_{LLI} and CE_{f} are poorly correlated to cycle life. We attribute this to the poor signal-to-noise inherent in measures of cell capacity in the absence of high-precision cycling [Ref. 39, 40]. The resistance measured at high SOCs also did not correlate to cycle life. Together, these results suggest that the low-SOC signal uniquely contains information related to cycle life that is measurable using ordinary cycler equipment. These results have been reproduced for different end-of-life definitions ranging between 50% and 80% in FIGS. 19 and 20.

To understand if R_{10s;5%SOC} can be used to improve battery lifetime prediction, we trained univariate prediction models with regularized linear regression models inspired by Severson et al. [Ref. 41]. The performance of the predictive models are summarized in Table 2.

TABLE 2
Training and testing errors for different lifetime prediction models. Values represent means (standard
deviations). The dummy regressor uses no features and simply returns the mean of the training set,
and hence is the baseline against which to judge other features. The other models use a Ridge
regression with nested cross-validation to determine the optimal regularization strength (see main
text for details). ‘Formation features’ refers to the three features from formation: Q_{LLI}, CE_{f}, and Q_{d}.

| | Data | | Room temp | | | | 45° C. | | | |
|---|---|---|---|---|---|---|---|---|---|---|
| | needed | | Train | | Test | | Train | | Test | |
| Dummy regressor | none | | 13.3 | (1.0) | 14.4 | (4.0) | 14.0 | (0.9) | 15.1 | (3.6) |
| R_{10 s; 5% SOC} | 3 | cycles | 6.9 | (0.5) | 8.0 | (2.8) | 6.5 | (0.6) | 7.4 | (2.9) |
| Q_{LLI} | formation | | 12.2 | (1.2) | 14.0 | (4.6) | 14.1 | (0.8) | 15.2 | (4.4) |
| CE_{f} | formation | | 12.2 | (1.2) | 13.8 | (4.5) | 14.1 | (0.7) | 15.1 | (4.3) |
| Q_{d} | formation | | 12.0 | (1.2) | 13.6 | (5.0) | 13.5 | (0.8) | 15.0 | (4.0) |
| Var(ΔQ₁₀₀₋₁₀(V)) | 100 | cycles | 11.6 | (1.7) | 14.4 | (5.2) | 10.3 | (1.1) | 11.5 | (4.7) |
| formation features | formation | | 12.8 | (1.3) | 14.5 | (5.1) | 13.4 | (1.1) | 14.1 | (4.0) |
| formation features + R_{10 s; 5% SOC} | 3 | cycles | 7.2 | (1.1) | 9.4 | (4.0) | 6.5 | (1.0) | 7.4 | (2.9) |

A dummy regressor, which predicts the mean of the training set and requires no lifetime data, is included as a benchmark. The model trained using R_{10s;5%SOC} achieved the lowest test error of 6.9% at room temperature, compared to 13.3% for the dummy regressor, and 6.5% at 45° C., compared to 14.0% for the dummy regressor. As a point of comparison, we have also included the Var(ΔQ₁₀₀₋₁₀(V)) metric introduced by Severson et al. [Ref. 41], defined as the variance in the capacity versus voltage curve between cycle 10 and cycle 100. With our dataset, this model did not yield a significant improvement over the dummy regressor. This result suggests that R_{10s;5%SOC} may be a stronger predictor of battery lifetime than Var(ΔQ₁₀₀₋₁₀(V)).

We repeated this study with multivariate regularized linear regressions: one using the three features from formation (Q_{LLI}, CE_{f}, and Q_{d}), and one using the three formation features plus R_{10s;5%SOC}. Using only the features from formation, no improvement over the dummy regressor was achieved. By including R_{10s;5%SOC} in the feature set, the test error was improved, but not more so than the univariate model using R_{10s;5%SOC} alone. This suggests that there is no useful information to be learned from the chosen set of formation features even in a higher-dimensional space. This result is counter-intuitive considering the important role that lithium consumption plays in determining battery lifetime [Ref. 9-14], which should be reflected in the formation features such as Q_{LLI} and CE_{f}. We speculate that the reason for the poor model performance using formation signals is not because these formation signals lack physical meaning, but that, due to the absence of high-precision cycling, the useful information within the signal is masked by the noise present in the data, e.g. due to current integration errors, temperature variations over the course of 10+ hours of formation, etc. R_{10s;5%SOC} is apparently able to overcome these limitation without any additional improvements to the testing hardware.

The total amount of data needed to exercise each predictive model is also summarized in Table 2. The model trained using R_{10s;5%SOC} required 3 cycles of lifetime testing. The two preceding cycles consist of slow-rate charge-discharge cycles as part of the reference performance test inserted at the beginning of the cycle life test. By comparison, Var(ΔQ₁₀₀₋₁₀(V)) requires 100 cycles of lifetime testing. For future implementations, R_{10s;5%SOC} can, in principle, be inserted directly into the formation protocol, further decreasing the amount of data needed.

Overall, the correlation and prediction results suggest that R_{10s;5%SOC} may be useful for advancing broad-scale efforts to improve cycle life prediction using minimal data-sets at the beginning of life. With the evidence provided so far, the R_{10s;5%SOC} can serve as a ranking metric, e.g. in the context of manufacturing quality control.

### 2.4 Physical Interpretation of Diagnostic Signals

Understanding the physical underpinnings of the diagnostic signals can help to assess whether a prediction framework leveraging these signals can generalize to new systems. In our case, we are interested in understanding whether prediction models using R_{10s;5%SOC} can generalize to new formation protocols or other manufacturing process changes. Towards this end, we first reviewed the commonly accepted theory of SEI passivation and showed how our observations of Q_{LLI} and CE_{f} supports this theory. Next, we showed how that R_{10s;5%SOC} is consistent with this theory, but provides a stronger and more easily measurable signal than these conventional measures based on Coulomb counting.

### 2.4.1 Impact of Fast Formation on Cycle Life

Lithium intercalation at graphite potentials higher than 0.25V to 0.5V vs. Li/Li⁺ is generally associated with the formation of a porous, poorly-passivated SEI film [Ref. 12, 14, 35, 42, 43]. By contrast, lithium intercalation at anode potentials below 0.25V-0.5V has been found to promote the formation of a more conductive and passivating SEI film [Ref. 33, 35]. Attia et al. [Ref. 33] showed that the reduction of ethylene carbonate (EC) at anode potentials above 0.5V vs Li/Li⁺ is non-passivating. This anode potential corresponds to a full cell voltage of below 3.5V, neglecting overpotential contributions. Hence, an ideal formation protocol would minimize the time spent charging below 3.5V while maximizing the time spent above 3.5V. The fast formation protocol from An et al. [Ref. 15] achieves this by rapidly charging the cell to above 3.9V at a 1 C charge rate, thus decreasing the time associated with the non-passivating EC reduction reaction. The protocol subsequently cycles the cell between 3.9V and 4.2V to promote the formation of a more passivating SEI film. These cycles increase the total time spent in this region while promoting more lithiation-induced electrode expansion and contraction, which exposes more graphite surfaces to further promote the formation of the passivating film. Focusing on the initial charge cycle, the fast formation protocol spends 2 minutes below 3.5V and 12.9 hours above 3.5V, while baseline formation spends 30 minutes below 3.5V and 9.4 hours above 3.5V. The 28-minute decrease in time spent below 3.5V decreases the amount of lithium lost to form the non-passivating SEI, while the 3.5-hour increase in time spent above 3.5V increases the amount of lithium lost to form the passivating SEI. Fast formation resulted in a net increase in total lithium consumed during formation, Q_{LLI}=Q_{c}−Q_{d}, by 23 mAh, as shown previously (see Table 1), indicating that the additional quantity of lithium lost to form the passivating SEI more than compensates for the quantity of lithium ‘saved’ from spending less time to generate the non-passivating SEI.

While fast formation cells exhibited poorer CE_{f} due to the extra lithium lost during formation, these cells lasted longer on the cycle life test. This result contradicts the conventional view that a higher initial coulombic efficiency (CE) leads to better cycle life [Ref. 39, 44]. We note that literature studies of CE typically do not include the first cycle efficiency, while our definition, CE_{f} distinctly captures the lithium lost during the formation cycle. It must be the case that the lithium lost during the first cycle in the passivating regime (i.e., at high cell potentials or low anode potentials) is distinct from the SEI that is continuously formed over the course of the cycle life. For example, a more passivating SEI can lower the rate of electrolyte reduction reactions associated with the formation of solid products that decrease the anode porosity and subsequently increase the propensity for lithium plating during charge [Ref. 45, 46]. In this way, a more passivating SEI could play a role in delaying the ‘knee’ observed in the cycle test data.

Overall, our results support the theory that consuming more lithium during low anode potentials during formation cycling can create a passivating SEI that is beneficial to cycle life [Ref. 33].

### 2.4.2 Low-SOC Resistance

To explore possible physical connections between R_{10s;5%SOC} and the other initial cell state metrics such as Q_{LLI}, we must first develop a physical interpretation of the low-SOC resistance. We attribute the measured full cell resistance at low SOCs mainly to the cathode charge transfer resistance, which rises steeply as the cathode approaches the fully lithiated state. The sharp increase in cathode resistance has been experimentally demonstrated by authors through half-cell measurements in both two-electrode [Ref. 47, 48] and three-electrode [Ref. 49] configurations. Mathematically, the Butler-Volmer equation predicts that the exchange current density, i₀, of the cathode approaches zero as the lithium concentration in the solid phase, c_{s,e}, approaches the maximum concentration, c_{s;max} [Ref. 50]:

$${i}_{0} ∝ {( \frac{{c}_{s ; max} - {c}_{s , e}}{{c}_{s ; max}} )}^{1 - α} \qquad ( 1 )$$

In this equation, a is the charge-transfer symmetry factor. While Ohmic resistance, film resistance, and diffusive processes could also contribute to the measured resistance at low SOCs, they are unlikely to be the main cause of the differences in low-SOC resistance measured between the two different formation protocols. The Ohmic component creates an instantaneous drop in voltage and arises due to contributions from the electrolyte, foils, tabs and binders. These components generally do not depend on SOC since their states are largely unaffected by the extent of lithiation of either electrode. The same has been shown to be true for film resistance [Ref. 49]. Hence, the maximum values for the Ohmic and film resistances are bounded by the lowest measured resistance across all SOCs. Since the magnitude of the resistance measured at 5% SOC is approximately three times greater than the lowest measured resistance, differences in the Ohmic resistance cannot explain the measured low-SOC resistance exhibited by fast formation cells. Finally, while solid-state diffusion processes could also play a role in the measured voltage polarization [Ref. 51], these processes are unlikely to dominate at time scales less than 10 seconds. We further verified that the large increase in resistance at low SOCs also holds under 1-second pulses (see FIG. 17), suggesting that diffusion limitations are unlikely to be a significant contributor to the measured differences in R_{10s;5%SOC}.

In summary, R_{10s;5%SOC} is an indicator of the cathode charge transfer resistance corresponding to 5% SOC.

### 2.4.3 Role of Fast Formation in Decreasing Low-SOC Resistance

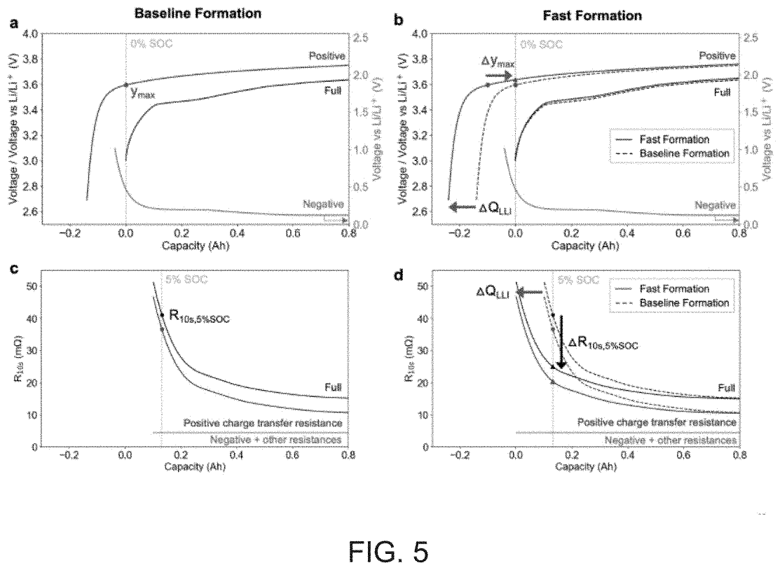

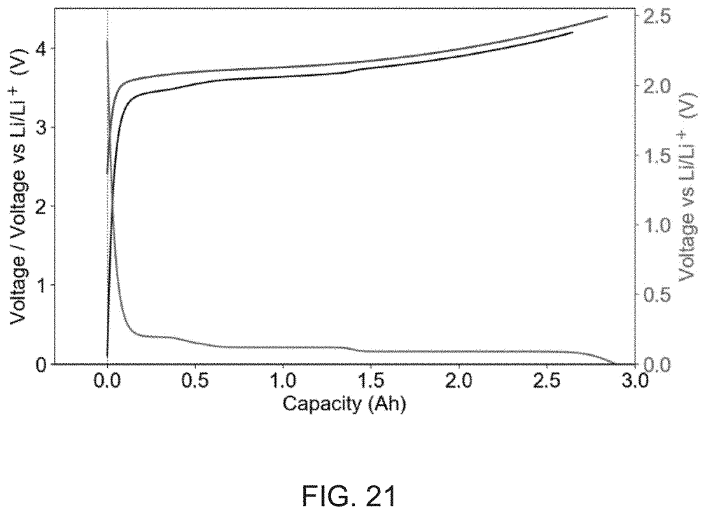

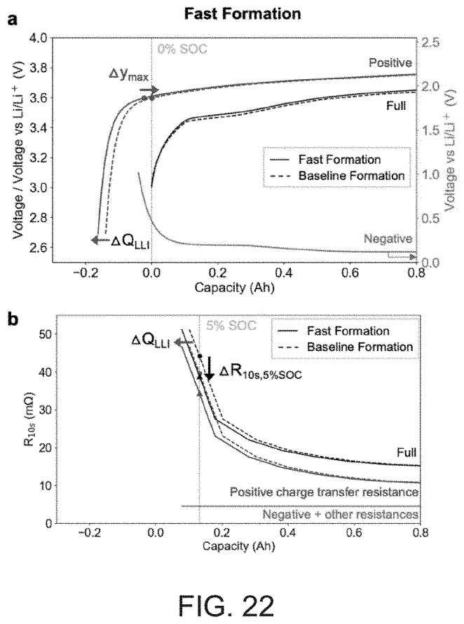

Fast formation decreased the measured low-SOC resistance. To understand why, we employed a toy model of electrode-specific equilibrium potential and resistance curves in FIG. 5. Panel (a) shows the relative alignment of the cathode and anode equilibrium potential curves after completion of baseline formation. The origin of the capacity axis corresponds to 0% SOC defined based on a minimum voltage of 3.0V. The gap between the anode and cathode curve endpoints is associated with the total lithium lost to the SEI during baseline formation, or Q_{LLI} [Ref. 52]. By comparison, the curves prior to formation have no gap, corresponding to Q_{LLI}=0 (see FIG. 21). Panel (c) shows the corresponding electrode-specific resistances. In this toy model, the cathode charge transfer resistance dominates the 10-second resistance at low SOCs, which is consistent with previous literature findings [Ref. 48, 49]. Panel (b) shows how fast formation introduces to a left-ward shift of the cathode equilibrium potential curve relative to the anode curve. This shift corresponds to the extra lithium consumed due to fast formation compared to baseline formation, ΔQ_{LLI.} (Note that the shift in this plot is exaggerated for graphical clarity. A more precise graphic corresponding to ΔQ_{LLI}=23 mAh is provided in FIG. 22.) Panel (d) shows that the corresponding cathode charge transfer resistance curve will also translate to the left by the same amount ΔQ_{LLI}. From the reference frame of the full cell, the measured 10-second resistance at 5% SOC will decrease by some amount ΔR_{10s;5%SOC}.

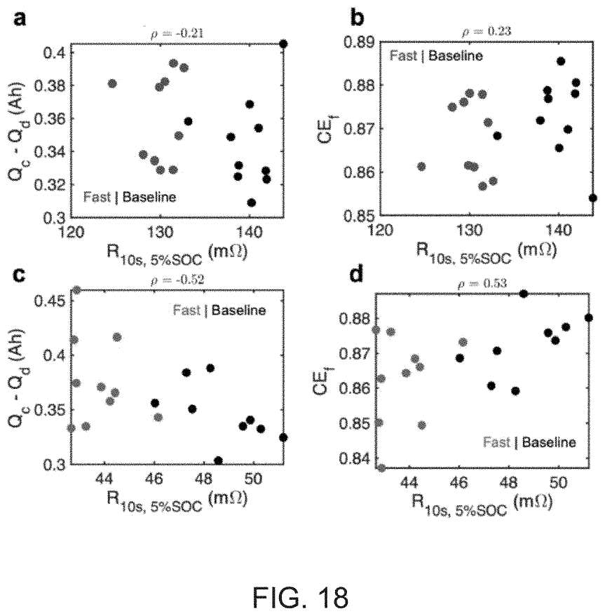

Several additional observations support the connection between ΔQ_{LLI} and R_{10s;5%SOC}. First, we note that R_{10s;5%SOC} appears to be positively correlated to CE_{f} and negatively correlated to Q_{LLI} (see FIG. 18). This result is in accordance with the theory, since lower R_{10s;5%SOC} and lower CE_{f} both imply more lithium consumed during formation, while higher R_{10s;5%SOC} implies less lithium consumed during formation, or lower Q_{LLI}. The strengths of the correlations are generally weak, with correlation coefficients ranging between −0.2 for room temperature cycling and −0.5 for 45° C. cycling. We attribute the weakness of the correlations to the poor signal-to-noise of capacity measurements using typical battery cycler equipment, which compounds in the absence of strict temperature control. Next, we note that, at mid to high SOCs, the slope of resistance versus capacity is approximately zero, and therefore, this region will not be sensitive to the impact of lithium consumption. Fast formation did not significantly increase the resistance in these regions (see FIGS. 15, 16), implying that the fast formation did not significantly modify the overall cell resistance. Therefore, R_{10s;5%SOC} is likely dominated by the effect of lithium consumption rather than any intrinsic change in the resistive properties of one or more cell components.

A basic calculation can be performed to compare the capacity of lithium consumed predicted by the R_{10s;5%SOC} metric against the value directly obtained through Coulomb counting. A linearization of the resistance versus capacity trend yields:

$$Δ {\tilde{Q}}_{LLI} \approx - \frac{dQ}{dR} {\vert}_{z = 0.05} \cdot Δ {R}_{z = 0.05} \qquad ( 2 )$$

where Δ\tilde{Q}_{LLI} is the estimated change in lithium consumed during formation, dQ/dR|_{z} is the slope of the capacity versus resistance curve linearized at SOC z, and ΔR_{z} is the corresponding resistance drop measured at SOC z. This equation holds under small changes in ΔR_{z}. Using the values from the result in FIG. 3 panel e, we calculate Δ\tilde{Q}_{LLI} to be 18 mAh. Comparatively, a direct measure of the lithium consumption through Coulomb counting yields ΔQ_{LLI}=23 mAh, as reported previously. Thus, while the estimated amount of lithium consumption using R_{10s;5%SOC} is in the correct order of magnitude, the numerical result under-estimates the measured ΔQ_{LLI}. Several factors may contribute to this error. First, the toy model neglects the impact of active material losses, which could play a role in increasing the measured R_{10s;5%SOC}. For example, a small fraction of graphite particles may become electrically-isolated due to lithiation-induced expansion and contraction during formation. While graphite particles are not known to fracture [Ref. 53], poor binder adhesion could lead to delamination of certain particles, lowering the availability of lithium sites in the graphite for cycling. This effectively translates into a ‘shrinkage’ of the anode equilibrium potential curve [Ref. 52] and effectively pushes the anode curve to the right relative to the cathode curve. This effect is not captured by our toy model, which ignores the effects of active material losses on the equilibrium potential curves. From this simple analysis, the loss of active material would account for the 5 additional mAh of ‘perceived’ lithium loss as measured by ΔQ_{LLI}. We also note that, in general, increases to the overall cell resistance would shift the entire resistance curve upward and decrease the measured ΔR_{10s;5%SOC}, causing ΔQ_{LLI} to be under-estimated. However, since fast formation did not increase the overall cell resistance, this factor is unlikely to explain the estimation error in our data. In the general case, the effect film resistance growth will need to be considered for this analysis.

Overall, the toy model demonstrates that an increase in Q_{LLI} can manifest as a decrease in R_{10s;5%SOC}.

### 2.4.4 Role of Lithium Consumption During Formation in Protecting the Cathode Against Over-Lithiation

A careful study of the electrode-specific equilibrium potential curves suggests an alternative explanation to why fast formation could have improved cycle life. Returning to FIG. 5 panel b, we note that the capacity corresponding to the extra lithium consumed from fast formation, ΔQ_{LLI}, is also associated with a decrease in the maximum cathode stoichiometry, Δyₘₐₓ, where yₘₐₓ represents the maximum cathode stoichiometry accessible within the full cell operational voltage window of the cycle life test. In other words, since fast formation consumed more lithium to create the SEI, the cathode becomes less fully lithiated when the cell is fully discharged. By comparison, the cathodes of baseline formation cells will be more lithiated at the end of discharge. Access to high cathode lithiation states is associated with higher levels of particle-level stress, leading to cracking of the ceramic oxide secondary particles [Ref. 54-56]. Stress-induced cracking over life can lead to electrical isolation of particles, resulting in loss of active sites. The cracking may also expose additional surface area, which could accelerate the rate of electrolyte decomposition reactions which may be linked to knees. Since a decrease to the maximum cathode lithiation effectively protects the cell against ‘over-discharging’, we speculate that this difference in yₘₐₓ could protect the fast formation cells against cathode cracking over the course of the cycle life test, leading to an improvement in the overall cycle life. This degradation mechanism is particularly relevant in our testing where every cycle ends on the minimum voltage target of 3.0V. Further degradation analysis can confirm this result, though we note that the differences may, in general, be very small, posing a challenge for detection using both ex-situ (e.g. coin cell [Ref. 48]) and in-situ (e.g. differential voltage [Ref. 52, 57]) methods.

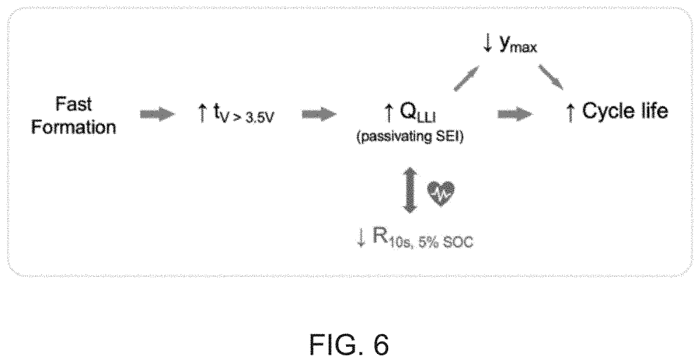

FIG. 6 describes the proposed connection between fast formation, the initial cell metrics, and cycle life.

### 2.4.5 Advantages of Low-SOC Resistance as an Early-Life Diagnostic Signal

The physical interpretation of the low-SOC resistance signal leads to several distinct advantages as an early-life diagnostic signal. First, since the cathode charge-transfer resistance increases as the cathode becomes fully lithiated, the signal becomes stronger as the measurement SOC decreases. It is therefore possible to improve the signal-to-noise ratio even further by discharging the cell to a low voltage prior to the measurement. Second, while measurements of Q_{LLI} requires full charge-discharge cycles during formation, R_{10s;5%SOC} can be used to extract information about Q_{LLI} within seconds. This makes the R_{10s;5%SOC} signal ideal for diagnosing differences in lithium consumption between formation protocols having different charge and discharge conditions which would pose challenges in the computation of Q_{LLI}=Q_{c}−Q_{d}. Third, the signal becomes stronger the earlier in life it is measured. This is because, over life, the continual loss of lithium inventory will cause the highly sloped region of the cathode charge-transfer resistance curve to become inaccessible during the normal full cell voltage operating window. Typically, diagnostic signals for lifetime become stronger as the cell becomes more aged [Ref. 41]. The predictive power for R_{10s;5%SOC} apparently benefits from being measured early on in life.

### 2.5 Diagnosing State of Health Beyond Cycle Life

Our discussion so far has focused only on evaluating the merits of R_{10s;5%SOC} for diagnosing cycle life. However, in real manufacturing settings, cycle life is only one of many considerations for adopting new formation protocols. Here, we introduce two such considerations: (1) impact to gas buildup over life, and (2) impact to aging variability over life. Through discussing these findings, we hope to highlight the importance of continued research to improve our ability to provide battery diagnostics beyond cycle life.

### 2.5.1 Pouch Cell Swelling at the End of Life

Swollen cells in a battery pack can compromise pack integrity and pose safety hazards for first-responders for electric vehicle fire accidents. Understanding the impact of formation protocols on cell swelling is therefore just as important as understanding the impact on cycle life for practical purposes.

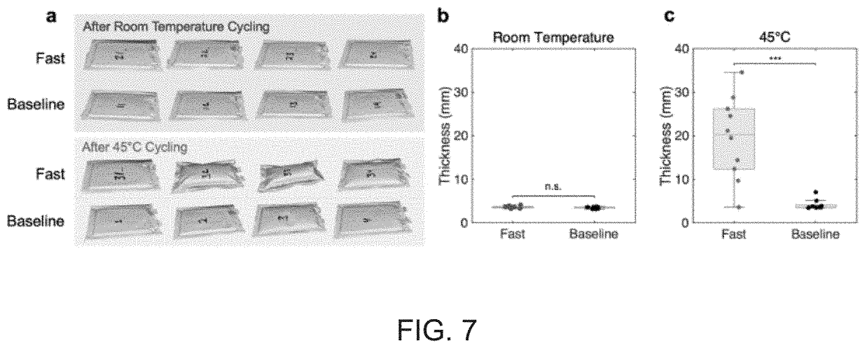

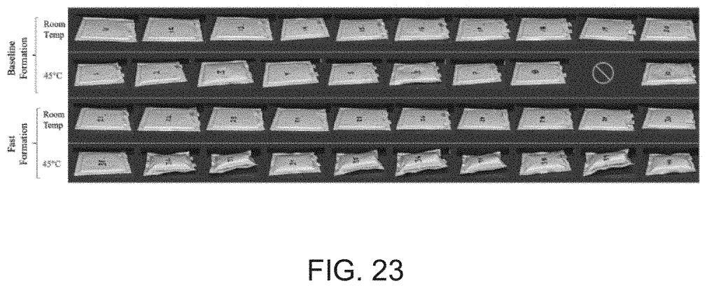

Fast formation caused a significant degree of swelling at the end of life for cells cycled at 45° C. (FIG. 7 panel a). At this temperature, 9 of 10 fast formation cells showed visible signs of swelling, compared to only 2 of 10 for baseline formation. None of the cells cycled at room temperature showed any appreciable degree of swelling. Panels (b,c) quantify the cell thicknesses as measured using a manual caliper, which represent the points of maximum deflection. At 45° C., fast formation cells had thicknesses measuring between ˜3.5 mm and ˜35 mm, and baseline formation cells had thicknesses measuring between ˜3.5 mm and ˜7 mm. The nominal pouch cell thickness is ˜3.5 mm. A complete set of images for all pouch cells is provided in FIG. 23. All swollen pouch cells were compliant and compressible, indicating that gas is occupying the space inside the pouch bags. Since the cells were de-gassed after formation, the measured swelling excludes the gas generated during formation and represent the accumulation of gas over the course of the cycle life test. The absence of gas during room temperature cycling indicates that the gas evolution is thermally activated.

In general, the gas built up inside the pouch cell represents the combination of gas both generated and consumed. Xiong et al. [Ref. 58] demonstrated that gas in NMC-graphite cells can be generated at the cathode and subsequently reduced at the anode via a ‘shuttle’ mechanism [Ref. 59]. At the cathode, gas species such as O₂, CO, and CO₂ can be generated through electrolyte oxidation pathways [Ref. 60, 61], and at the anode, gas species can be further reduced into solid products [Ref. 60]. Hence, the fast formation process must be either accelerating the gas generation rate, decreasing the gas consumption rate, or both. Furthermore, Krause [Ref. 62] and Chevrier et al. [Ref. 63] have reported that the reduction of CO₂ at the anode contributes to the SEI growth process and have a stabilizing effect. Since the fast formation cells demonstrate increased cycle life, one possibility is that more CO₂ is being generated at the cathode and reduced at the anode to further improve the passivation of the SEI.

The variability in the pouch swelling suggests that the gas evolution process is inconsistent from cell to cell. The pouch cells were inspected three months after the end of the cycle life test and were shown to retain their degree of swelling, indicating that the pouch cells are not leaky, and thus the differences in cell swelling are physically significant. Inconsistencies in cell stack pressure during the cycling test may have contributed to the measured variability in gas buildup. The impact of external pressure on controlling evolution has been demonstrated in silicon-containing systems where electrode volume expansion is high [Ref. 64-66]. Muller et al. [Ref. 66] specifically found that, for Si/C/NMC811 pouch cells, the variability in cell degradation could be reduced by controlling the mechanical compression of the cells. These same principles could also be applied to graphite-only systems to lower the variability in gas buildup.

### 2.5.2 Aging Variability

Adopting a new formation protocol in practice also requires a keen understanding of cell aging variability. For example, cells with non-uniform capacity fade could take longer to balance in a pack and cause a deterioration of charging times. These issues could lead to products being retired earlier, compounding the existing battery recycling challenges [Ref. 67]. Non-uniform cell degradation will also be more difficult to re-purpose [Ref. 68] into new modules, creating higher barriers for pack reuse.

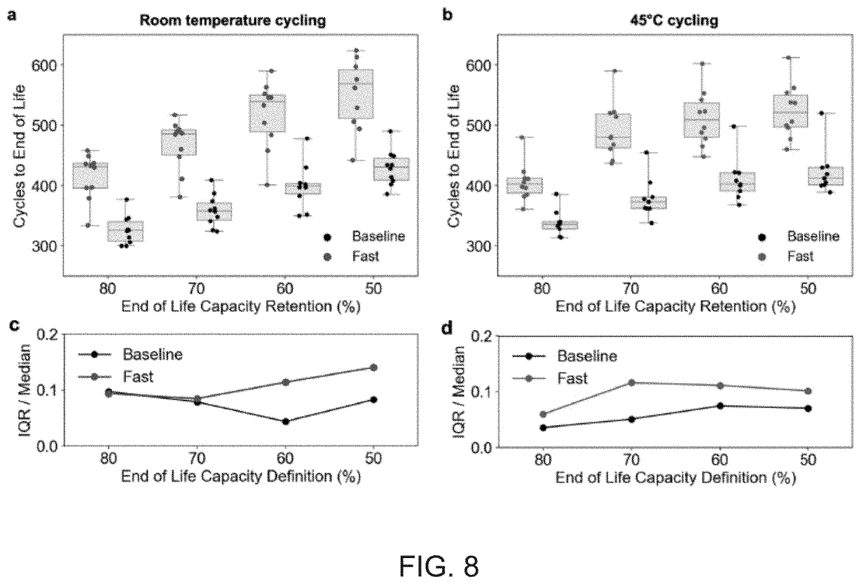

FIG. 2 at panels b,d compares the distribution of end-of-life outcomes between fast formation and baseline formation, where end-of-life corresponds to 70% capacity retention. The inter-quartile range (IQR) shows that the aging variability for fast formation cells is higher than that of baseline formation cells, a result which holds at both temperatures and across different end-of-life definitions (see FIG. 8). A key question is whether fast formation created more heterogeneous aging behavior which caused higher variability in aging, or if the higher variability is simply due to the cells lasting longer. To answer this question, we employed the modified signed-likelihood ratio test [Ref. 69] to check for equality of the coefficients of variation, defined as the ratio between the standard deviation and the mean cycle life. The resulting p-values were greater than 0.05 in all cases. Therefore, with the available data, it cannot be concluded that fast formation increased the variation in aging beyond the effect of improving cycle life. While a relationship between formation protocol and aging variability may still generally exist, this difference cannot be ascertained rigorously with our samples size (n=10). Larger samples sizes may be needed to make statistically sound conclusions about the impact of formation protocol on aging variability.

### 3. Experimental Procedures

### 3.1 Resource Availability

All materials are commercially available, with the exception of the CMC binder material used in the anode formulation, which is proprietary.

### 3.2 Cell Build Process

The cathode was comprised of 94:3:3 TODA North America NMC 111, Timcal C65 conductive additive, and Kureha 7208 PVDF. The slurry was mixed in a Primix 5 L in a step-wise manner, starting with a dry solids homogenization, wetting with NMP, and then addition of the PVDF resin. The slurry was allowed to mix overnight under static vacuum with agitation from both the double helix blades (30 rpm) and the high-speed disperser blade (1600 rpm). The final slurry was gravity filtered through a 125 mm paint filter before coating on a CIS roll-to-roll coating machine. The electrode was coated using the reverse comma method at 2 m/min. The final double-sided loading was 34.45 mg/cm². The anode was comprised of 97:0:(1.5/1.5) Hitachi MAG-E3 graphite, no conductive additive, and equal parts CMC and SBR. While the identity of the CMC material is proprietary and cannot be disclosed, the SBR used was Zeon BM-451B. The graphite and pre-dispersed CMC were mixed in the Prim ix 5 L mixer prior to further let-down with de-ionized water and overnight dispersion under static vacuum and double helix blade agitation (40 rpm). Prior to coating, the SBR was added and mixed in with helical blade agitation for fifteen minutes under active vacuum. The final slurry was gravity filtered through a 125 mm paint filter before coating on a CIS roll-to-roll coating machine. The electrode was coated using the reverse comma technique at 1.5 m/min. The final double-sided loading was 15.7 mg/cm².

Both anode and cathode were calendared at room temperature to approximately 30% porosity prior to being transferred to a −40° C. dew point dry room for final cell assembly and electrolyte filling. The cells, comprising 7 cathodes and 8 anodes, were z-fold stacked, ultrasonically welded, and sealed into formed pouch material using mPlus supplied automatic fabrication equipment. The assembled cells were placed in a vacuum oven at 50° C. overnight to fully dry prior to electrolyte addition. Approximately 10.5 g of electrolyte (1.0M LiPF₆ in 3:7 EC:EMC v/v+2 wt % VC from Soulbrain) was manually added to each cell prior to the initial vacuum seal (50 Torr, 5 sec). The total mass of all components of the battery is 56.6±0.3 g.

The now-wetted cells were each placed under compression between fiberglass plates held in place using spring-loaded bolts. The compression fixtures are designed to allow the gas pouch to protrude and freely expand in the event of gas generation during formation. All cells were allowed to fully wet for 24 hours prior to beginning the formation process.

After formation, the cells were removed from the pressure fixtures, returned to the −40° C. dew point dry room, and degassed. The degassing process was completed in an mPlus degassing machine, automatically piercing the gas pouch, drawing out any generated gas during the final vacuum seal (50 Torr, 5 sec) and then placing the final seal on the cell. Cells are manually trimmed to their final dimensions before being returned to their pressure fixtures.

### 3.3 Formation Protocols

FIG. 9 at panel b describes the two different formation protocols used in this Example. The fast formation protocol borrows from the “Ultra-fast formation protocol” reported in An et al. [Ref. 15] and Wood et al. [Ref. 16] In this protocol, the cell is brought to 3.9V using a 1 C (2.36 Ah) charge, followed by five consecutive charge-discharge cycles between 3.9V and 4.2V at C/5, and finally ending on a 1 C discharge to 2.5V. Each charge step terminates on a CV hold until the current falls below C/100. A C/10 charge and C/10 discharge cycle was appended at the end of the test to measure the post-formation cell discharge capacity. A 6-hour step was included in between the C/10 charge-discharge steps to monitor the voltage decay. The formation sequence takes 14 hours to complete after excluding time taken for diagnostic steps.

A baseline formation protocol was also implemented which serves as the control for comparing against the performance of fast formation. This protocol consists of three consecutive C/10 charge-discharge cycles between 3.0V and 4.2V. A 6-hour rest was also added between the final C/10 charge-discharge step to monitor the voltage decay signal. The total formation time amounts to 50 hours after excluding the diagnostic steps. Formation was conducted at room temperature for all cells and across both formation protocols.

All formation cycling was conducted on a Maccor Series 4000 cycler (0-5V, 30 mA-1 A, auto-ranging). Following formation, one cell (#9) was excluded from the study of this Example due to tab weld issues. Consequently, the sample count for the ‘baseline formation, 45° C.’ cycling group was decreased to 9. The remaining groups had sample counts of 10.

The mean cell energy measured at a 1 C discharge rate from 4.2V to 3.0V at room temperature is 8.13 Wh. Full cell level volumetric stack energy density is estimated to be 365 Wh/L based on a volume of 69 mm×101 mm×71 mm×3.2 mm, and the gravimetric stack energy density is estimated to be 144 Wh/kg based on a total cell mass of 56.6 g.

### 3.4 Cycle Life Test

Following completion of formation cycling, cells were placed in spring-loaded compression fixtures to maintain a uniform stack pressure. Half of the cells from each formation protocol were placed in a thermal chamber (Espec) with a measured temperature of 44.2±0.1° C. The remaining cells were left at room temperature and were exposed to varying temperatures throughout the day (24.5±0.6° C.). Long-term cycle life testing was conducted on a Maccor Series 4000 cycler (0-5V, 10 A, auto-ranging). The cycle life test protocol was identical for all cells and consisted of 1 C (2.37 A), CCCV charges to 4.2V and 1 C discharges to 3.0V. At every 50 to 100 cycles, the test was interrupted so that a Reference Performance Test (RPT) could be performed [Ref. 36]. The RPT consists of a C/3 charge-discharge cycle, a C/20 charge-discharge cycle, followed by the Hybrid Pulse Power Characterization (HPPC) protocol [Ref. 37]. The HPPC test is used to extract 10-second discharge resistance (Rios) as a function of SOC (see FIG. 14). Every cell was cycled until the discharge capacity was less than 1.18 Ah, corresponding to less than 50% capacity remaining. The total test time varied between 3 to 4 months and the total cycles achieved ranged between 400 and 600 cycles.

### 3.5 Statistical Significance Testing

The standard Student's t-test for two samples is used throughout this paper to check if differences in measured outcomes between the two different formation protocols are statistically significant. The p-value is used to quantify the level of marginal significance within the statistical hypothesis test and represents the probability that the null hypothesis is true. A p-value less than 0.05 is used to reject the null hypothesis that the population means are equal. All measured outcomes are assumed to be normally distributed.

Box-and-whisker plots are used throughout this Example to summarize distributions of outcomes. Boxes denote the interquartile range (IQR) and whiskers show the minimum and maximum values in the set. No outlier detection methods are employed here due to the small sample sizes (n<10).

### 3.6 Predictive Model

Due to the small number of data points available, the model prediction results are sensitive to which cells are chosen for validation. Therefore, we used nested cross-validation [Ref. 70] in order to evaluate the regularized linear regression model on all the data without over-fitting. The nested cross-validation algorithm was as follows: first, we separated the data into 20% ‘validation’ and 80% ‘train/test’. Then, we performed four-fold cross-validation on the ‘train/test’ data to find the optimal regularization strength for Ridge regression, α*, using grid search. Finally, we trained the Ridge regression algorithm with regularization strength α*, using all of the train/test data, and evaluated the error on the validation data. We repeated this process for 1000 random train-test/validation splits and reported the mean and standard deviation of the mean percent error for each run,

$$MPE [ \% ] = \frac{1}{N} {\sum }_{k = 1}^{N} \frac{{y}_{k}^{pred} - {y}_{k}^{true}}{{y}_{k}^{true}} . \qquad ( 3 )$$

Each run can select a different optimal regularization strength α*.

### 3.7 Toy Model of Electrode-Specific Equilibrium Potential Curves and Resistance Curves

To construct the baseline formation curve shown in FIG. 5 at panel a, a full cell near-equilibrium potential curve is extracted from the C/20 charge cycle as part of the reference performance test (RPT). A randomly selected cell from the 45° C. cycling group was selected for this data extraction. Cathode and anode near-equilibrium potential curves are adapted from Mohtat et al. [Ref. 27]. The electrode-specific utilization windows are determined by fitting the anode and cathode curves to match the full cell curve by solving a non-linear least squares optimization problem as outlined in Lee et al. [Ref. 71]. The resulting cathode and anode alignment minimizes the squared error of the modeled versus the measured full cell voltage. The fast formation curve equilibrium potential curve was constructed by shifting the cathode curve horizontally and re-computing the full cell voltage curve. In FIG. 5 at panel b, the cathode curve was shifted by −100 mAh for visual clarity.

The full cell resistance curves in FIG. 5 at panels c,d source data from the HPPC sequence as part of the same RPT used to obtain the equilibrium potential curve shown in FIG. 5 at panels a,b. A cubic spline fit was used to create a smooth curve for the toy model. To break down the resistance contribution into ‘positive charge transfer resistance’ and ‘negative+other resistances’, a baseline reference resistance R_{ref} was first defined as the minimum measured full cell resistance below 1 Ah. A fraction, f, of R_{ref} is then assigned to the ‘negative+other resistances’, which is assumed to take a constant value for capacities below 1 Ah. The remaining resistance is then assigned to the cathode charge transfer resistance. In FIG. 5, f was chosen to be 0.7, though the same numerical results hold for all f∈(0,1).

### Glossary of Terms

CC—constant current

CCCV—constant current constant voltage

CE—coulombic efficiency

CE_{f}—formation coulombic efficiency

CEI—cathode electrolyte interphase

CMC—carbon methyl cellulose

CV—constant voltage

EC—ethylene carbonate

EMC—ethyl methyl carbonate

HPPC—hybrid pulse power characterization

IQR—inter-quartile range

LiPF₆—lithium hexafluorophosphate

NMC—Nickel manganese cobalt

NMP—n-methyl-2-pyrrolidone

PVDF—polyvinylidene fluoride

Q_{c}—first cycle charge capacity

Q_{d}—post-formation C/10 discharge capacity

Q_{LLI}—capacity of lithium inventory lost during formation=Qc Qd

R₁₀ₛ—10-second discharge resistance

R_{10s;5%SOC}—10-second discharge resistance measured at 5% SOC

RPT—reference performance test

SBR—styrene butadiene rubber

SEI—solid electrolyte interphase

SOC—state of charge

VC—vinylene carbonate

yₘₐₓ—maximum cathode stoichiometry

### REFERENCES

1. Australian Trade and Investment Commission. The Lithium-Ion Battery Value Chain: New Economy Opportunities for Australia tech. rep. (2018), 56.
2. Benchmark Minerals Intelligence. EV Battery arms race enters new gear with 115 megafactories, Europe sees most rapid growth 2019.
3. Mackenzie, W. Global lithium-ion cell manufacturing capacity to quadruple to 1.3 TWh by 2030 2020.
4. Liu, Y., Zhang, R., Wang, J. & Wang, Y. Current and future lithium-ion battery manufacturing. iScience 24, 102332. ISSN:25890042. https://doi.org/10.1016/j.isci.2021.102332 (2021).
5. Nelson, P. A., Bloom, K. G. & I Dees, D. W. P. A. Nelson, K. G. Gallagher, I. Bloom, D. W. Dees, Modeling the performance and cost of lithium-ion batteries for electric-drive vehicles, Electrochemical Energy Storage Theme, Chemical Sciences and Engineering division, Argonne National Laboratory, September, 121. https://publications.anl.gov/anlpubs/2011/10/71302.pdf (2011).
6. Duffner, F., Mauler, L. Wentker, M., Leker, J. &Winter, M. Large-scale automotive battery cell manufacturing: Analyzing strategic and operational effects on manufacturing costs. International Journal of Production Economics 232, 107982. ISSN: 09255273. https://doi.org/10.1016/j.ijpe.2020.107982 (2021).
7. Kuhlmann, K., Wolf, S., Pieper, C., Xu, G. & Ahmad, J. The Future of Battery Production for Electric Vehicles tech. rep. (2018), 1-22.
8. Wood, D. L., Li, J. & Daniel, C. Prospects for reducing the processing cost of lithium ion batteries. Journal of Power Sources 275, 234-242. ISSN: 03787753. http://dx.doi.org/10.1016/j.jpowsour.2014.11.019 (2015).
9. Winter, M. The solid electrolyte interphase—The most important and the least understood solid electrolyte in rechargeable Li batteries. Zeitschrift fur Physikalische Chemie 223, 1395-1406. ISSN: 09429352 (2009).
10. An, S. J. et al. The state of understanding of the lithium-ion-battery graphite solid electrolyte interphase (SEI) and its relationship to formation cycling. Carbon 105, 52-76. ISSN: 00086223. http://dx.doi.org/10.1016/j. carbon.2016.04.008 (2016).
11. Wang, A., Kadam, S., Li, H., Shi, S. & Qi, Y. Review on modeling of the anode solid electrolyte interphase (SEI) for lithium-ion batteries. npj Computational Materials 4. ISSN: 20573960. http://dx.doi.org/10.1038/s41524-018-0064-0 (2018).
12. Peled, E. & Menkin, S. Review—SEI: Past, Present and Future. Journal of The Electrochemical Society 164, A1703-A1719. ISSN: 0013-4651 (2017).
13. Goers, D., Spahr, M. E., Leone, A., Märkle, W. & Novák, P. The influence of the local current density on the electrochemical exfoliation of graphite in lithium-ion battery negative electrodes. Electrochimica Acta 56, 3799-3808. ISSN:00134686. http://dx.doi.org/10.1016/j.electacta.2011.02.046 (2011).
14. Lu, P., Li, C., Schneider, E. W. & Harris, S. J. Chemistry, impedance, and morphology evolution in solid electrolyte interphase films during formation in lithium ion batteries. Journal of Physical Chemistry C 118, 896-903. ISSN: 19327447 (2014).
15. An, S. J., Li, J., Du, Z., Daniel, C. & Wood, D. L. Fast formation cycling for lithium ion batteries. Journal of Power Sources 342, 846-852. ISSN: 03787753. http://dx.doi.org/10.1016/j.jpowsour.2017.01.011 (2017).
16. Wood, D. L., Li, J. & An, S. J. Formation Challenges of Lithium-Ion Battery Manufacturing. Joule 3, 2884-2888. ISSN: 25424351. https://doi.org/10.1016/j.joule.2019.11.002 (2019).
17. Mao, C. et al. Balancing formation time and electrochemical performance of high energy lithium-ion batteries. Journal of Power Sources 402, 107-115. ISSN: 03787753. https://doi.org/10.1016/j.jpowsour.2018.09.019 (2018).
18. Müller, V. et al. Introduction and application of formation methods based on serial-connected lithium-ion battery cells. Journal of Energy Storage 14, 56-61. ISSN: 2352152X. http://dx.doi.org/10.1016/j.est.2017.09.013 (2017).
19. Antonopoulos, B. K., Stock, C., Maglia, F. & Hoster, H. E. Solid electrolyte interphase: Can faster formation at lower potentials yield better performance? Electrochimica Acta 269, 331-339. ISSN: 00134686. https://doi.org/10.1016/j.electacta.2018.03.007 (2018).
20. Zhang, S. S., Xu, K. & Jow, T. R. Optimization of the forming conditions of the solid-state interface in the Li-ion batteries. Journal of Power Sources 130, 281-285. ISSN: 03787753 (2004).
21. Heimes, H. H. et al. The Effects of Mechanical and Thermal Loads during Lithium-Ion Pouch Cell Formation and Their Impacts on Process Time. Energy Technology 8, 1-12. ISSN: 21944296 (2020).
22. Ryan, M. et al. Effect of Li plating during formation of lithium ion batteries on their cycling performance and thermal safety. Journal of Power Sources 484, 0-7 (2021).
23. Pathan, T. S., Rashid, M., Walker, M., Widanage, W. D. & Kendrick, E. Active formation of Li-ion batteries and its effect on cycle life. Journal of Physics: Energy 1, 044003. ISSN: 2515-7655 (2019).
24. Müller, V., Kaiser, R., Poller, S. & Sauerteig, D. Importance of the constant voltage charging step during lithium-ion cell formation. Journal of Energy Storage 15, 256-265. ISSN: 2352152X. http://dx.doi.org/10.1016/j.est.2017.11.020 (2018).
25. Rago, N. D. et al. Effect of formation protocol: Cells containing Si-Graphite composite electrodes. Journal of Power Sources 435, 126548. ISSN: 03787753. https://doi.org/10.1016/j.jpowsour.2019.04.076 (2019).
26. Lee, H. H. et al. A fast formation process for lithium batteries. Journal of Power Sources 134, 118-123. ISSN: 03787753 (2004).
27. Mohtat, P., Lee, S., Sulzer, V., Siegel, J. B. & Stefanopoulou, A. G. Differential Expansion and Voltage Model for Li-ion Batteries at Practical Charging Rates. Journal of The Electrochemical Society 167, 110561. ISSN: 1945-7111 (2020).
28. Bommier, C. et al. In Operando Acoustic Detection of Lithium Metal Plating in Commercial LiCoO2/Graphite Pouch Cells. Cell Reports Physical Science 1, 100035. ISSN: 26663864. https://doi.org/10.1016/j.xcrp.2020.100035 (2020).
29. Davies, G. et al. State of Charge and State of Health Estimation Using Electrochemical Acoustic Time of Flight Analysis. Journal of The Electrochemical Society 164, A2746-A2755. ISSN: 0013-4651 (2017).
30. Knehr, K. W. et al. Understanding Full-Cell Evolution and Non-chemical Electrode Crosstalk of Li-Ion Batteries. Joule 2, 1146-1159. ISSN: 25424351. https://doi.org/10.1016/j.joule.2018.03.016 (2018).
31. Deng, Z. et al. General Discharge Voltage Information Enabled Health Evaluation for Lithium-Ion Batteries. IEEE/ASME Transactions on Mechatronics, 1-1. ISSN: 1083-4435 (2020).
32. Willenberg, L. et al. The Development of Jelly Roll Deformation in 18650 Lithium-Ion Batteries at Low State of Charge. Journal of The Electrochemical Society 167, 120502. ISSN: 1945-7111 (2020).
33. Attia, P. M., Harris, S. & Chueh, W. Benefits of Fast Battery Formation Processes in a Model System. Journal of The Electrochemical Society. ISSN: 0013-4651 (2021).
34. Kim, S. P., Duin, A. C. & Shenoy, V. B. Effect of electrolytes on the structure and evolution of the solid electrolyte interphase (SEI) in Li-ion batteries: A molecular dynamics study. Journal of Power Sources 196, 8590-8597. ISSN:03787753. http://dx.doi.org/10.1016/j.jpowsour.2011.05.061 (2011).
35. Zhang, S., Ding, M. S., Xu, K., Allen, J. & Jow, T. R. Understanding solid electrolyte interface film formation on graphite electrodes. Electrochemical and Solid-State Letters 4, 206-209. ISSN: 10990062 (2001).
36. Dubarry, M. & Baure, G. Perspective on commercial Li-ion battery testing, best practices for simple and effective protocols. Electronics (Switzerland) 9. ISSN: 20799292 (2020).
37. Christopherson, J. P. Battery Test Manual for Plug-In Hybrid Electric Vehicles tech. rep. (Idaho National Laboratory, Idaho Falls, Id., 2015). http://www.inl.gov/technicalpublications/Documents/3952791.pdf.
38. Dahn, J. R. Phase diagram of Li_{x}C_{6}. Physical Review B 44, 9170-9177 (1991).
39. Smith, A. J., Burns, J. C., Xiong, D. & Dahn, J. R. Interpreting High Precision Coulometry Results on Li-ion Cells. Journal of The Electrochemical Society 158, A1136. ISSN: 00134651 (2011).
40. Fathi, R. et al. Ultra High-Precision Studies of Degradation Mechanisms in Aged LiCoO₂/Graphite Li-Ion Cells. Journal of The Electrochemical Society 161, A1572-A1579. ISSN: 0013-4651 (2014).
41. Severson, K. A. et al. Data-driven prediction of battery cycle life before capacity degradation. Nature Energy 4, 383-391. ISSN: 20587546. http://dx.doi.org/10.1038/s41560-019-0356-8 (2019).
42. Edström, K., Herstedt, M. & Abraham, D. P. A new look at the solid electrolyte interphase on graphite anodes in Li-ion batteries. Journal of Power Sources 153, 380-384. ISSN: 03787753 (2006).
43. Lu, P. & Harris, S. J. Lithium transport within the solid electrolyte interphase. Electrochemistry Communications 13, 1035-1037. ISSN: 13882481. http://dx.doi.org/10.1016/j.elecom.2011.06.026 (2011).
44. Burns, J. C. et al. Predicting and Extending the Lifetime of Li-Ion Batteries. Journal of The Electrochemical Society 160, A1451-A1456. ISSN: 0013-4651 (2013).
45. Reniers, J. M., Mulder, G. & Howey, D. A. Review and Performance Comparison of Mechanical-Chemical Degradation Models for Lithium-Ion Batteries. Journal of The Electrochemical Society 166, A3189-A3200. ISSN: 0013-4651 (2019).
46. Yang, X. G., Leng, Y., Zhang, G., Ge, S. & Wang, C. Y. Modeling of lithium plating induced aging of lithium-ion batteries: Transition from linear to nonlinear aging. Journal of Power Sources 360, 28-40. ISSN: 03787753. http://dx.doi.org/10.1016/j.jpowsour.2017.05.110 (2017).
47. Verma, A. et al. Galvanostatic Intermittent Titration and Performance Based Analysis of LiNi_{0.5}Co_{0.2}Mn_{0.3}O₂ Cathode. Journal of The Electrochemical Society 164, A3380-A3392. ISSN: 0013-4651 (2017).
48. Abraham, D. P. Diagnostic Examination of Generation 2 Lithium-Ion Cells and Assessment of Performance Degradation Mechanisms prepared by Chemical Engineering Division tech. rep. (Argonne National Laboratory, 2005).
49. An, S. J., Li, J., Daniel, C., Kalnaus, S. & Wood, D. L. Design and Demonstration of Three-Electrode Pouch Cells for Lithium-Ion Batteries. Journal of The Electrochemical Society 164, A1755-A1764. ISSN: 0013-4651 (2017).
50. Plett, G. L. Battery Management Systems Volume I: Battery Modeling 110-119 (2015).
51. Yang, S. et al. Determination of the chemical diffusion coefficient of lithium ions in spherical Li[Ni_{0.5}Mn_{0.3}Co_{0.2}]O₂. Electrochimica Acta 66, 88-93. ISSN: 00134686. http://dx.doi.org/10.1016/j.electacta.2012.01.061 (2012).
52. Dubarry, M., Truchot, C. & Liaw, B. Y. Synthesize battery degradation modes via a diagnostic and prognostic model. Journal of Power Sources 219, 204-216. ISSN: 03787753. http://dx.doi.org/10.1016/j.jpowsour.2012.07.016 (2012).
53. Takahashi, K. & Srinivasan, V. Examination of Graphite Particle Cracking as a Failure Mode in Lithium-Ion Batteries: A Model-Experimental Study. Journal of The Electrochemical Society 162, A635-A645. ISSN: 0013-4651 (2015).
54. Li, M., Feng, M., Luo, D. & Chen, Z. Fast Charging Li-Ion Batteries for a New Era of Electric Vehicles. Cell Reports Physical Science 1, 100212. ISSN: 26663864. http://dx.doi.org/10.1016/j.xcrp.2020.100212 (2020).
55. Watanabe, S., Kinoshita, M., Hosokawa, T., Morigaki, K. & Nakura, K. Capacity fade of LiAl_{y}Ni_{1-x-y}CoₓO₂ cathode for lithium-ion batteries during accelerated calendar and cycle life tests (surface analysis of LiAl_{y}Ni_{1-x-y}CoₓO₂ cathode after cycle tests in restricted depth of discharge ranges). Journal of Power Sources 258, 210-217. ISSN: 03787753. http://dx.doi.org/10.1016/j.jpowsour.2014.02.018 (2014).
56. Zhang, S. S. Problems and their origins of Ni-rich layered oxide cathode materials. Energy Storage Materials 24, 247-254. ISSN: 24058297. https://doi.org/10.1016/j.ensm.2019.08.013 (2020).
57. Lee, S., Siegel, J. B., Stefanopoulou, A. G., Lee, J.-W. & Lee, T.-K. Electrode State of Health Estimation for Lithium Ion Batteries Considering Half-cell Potential Change Due to Aging. Journal of The Electrochemical Society 167, 090531. ISSN: 1945-7111 (2020).
58. Xiong, D. J. et al. Studies of Gas Generation, Gas Consumption and Impedance Growth in Li-Ion Cells with Carbonate or Fluorinated Electrolytes Using the Pouch Bag Method. Journal of The Electrochemical Society 164, A340-A347. ISSN:0013-4651 (2017).
59. Ellis, L. D. et al. Quantifying, Understanding and Evaluating the Effects of Gas Consumption in Lithium-Ion Cells. Journal of The Electrochemical Society 164, A3518-A3528. ISSN: 0013-4651 (2017).
60. Rowden, B. & Garcia-Araez, N. A review of gas evolution in lithium ion batteries. Energy Reports 6, 10-18. ISSN:23524847. https://doi.org/10.1016/j.egyr.2020.02.022 (2020).
61. Jung, R., Metzger, M., Maglia, F., Stinner, C. & Gasteiger, H. A. Oxygen Release and Its Effect on the Cycling Stability of LiNiₓMn_{y}Co_{z}O₂ (NMC) Cathode Materials for Li-Ion Batteries. Journal of The Electrochemical Society 164, A1361-A1377. ISSN: 0013-4651 (2017).
62. Krause, L. J., Chevrier, V. L., Jensen, L. D. & Brandt, T. The Effect of Carbon Dioxide on the Cycle Life and Electrolyte Stability of Li-Ion Full Cells Containing Silicon Alloy. Journal of The Electrochemical Society 164, A2527-A2533. ISSN:0013-4651 (2017).
63. Chevrier, V. L. et al. Design of Positive Electrodes for Li-Ion Full Cells with Silicon. Journal of The Electrochemical Society 165, A2968-A2977. ISSN: 0013-4651 (2018).
64. Barai, A. et al. The effect of external compressive loads on the cycle lifetime of lithium-ion pouch cells. Journal of Energy Storage 13, 211-219. ISSN: 2352152X (2017).
65. De Sutter, L. et al. Comprehensive Aging Analysis of Volumetric Constrained Lithium-Ion Pouch Cells with High Concentration Silicon-Alloy Anodes. Energies 11, 5-14. ISSN: 19961073 (2018).
66. Müller, V. et al. Effects of Mechanical Compression on the Aging and the Expansion Behavior of Si/C-Composite|NMC811 in Different Lithium-Ion Battery Cell Formats. Journal of The Electrochemical Society 166, A3796-A3805. ISSN: 0013-4651 (2019).
67. Harper, G. et al. Recycling lithium-ion batteries from electric vehicles. Nature 575, 75-86. ISSN: 14764687. http://dx.doi.org/10.1038/s41586-019-1682-5 (2019).
68. Engel, H., Hertzke, P. & Siccardo, G. Second-life EV batteries: The newest value pool in energy storage tech. rep. April (2019). https://www.mckinsey.com/industries/automotive-and-assembly/our-insights/second-life-ev-batteries-the-newest-value-pool-in-energy-storage.
69. Krishnamoorthy, K. & Lee, M. Improved tests for the equality of normal coefficients of variation. Computational Statistics 29, 215-232. ISSN: 09434062 (2014).
70. Krstajic, D., Buturovic, L. J., Leahy, D. E. & Thomas, S. Cross-validation pitfalls when selecting and assessing regression and classification models. Journal of Cheminformatics 6, 1-15. ISSN: 17582946 (2014).
71. Lee, S., Siegel, J. B., Stefanopoulou, A. G., Lee, J.-W. & Lee, T.-K. Electrode State of Health Estimation for Lithium Ion Batteries Considering Half-cell Potential Change Due to Aging. J Electrochem Soc 167, 90531 (May 2020).

The citation of any document or reference is not to be construed as an admission that it is prior art with respect to the present invention.

Thus, the invention provides methods for making electrochemical devices, such as lithium ion batteries and lithium metal batteries. In particular, the invention provides improved early-life diagnostics that enable faster battery formation protocols.

In light of the principles and example embodiments described and illustrated herein, it will be recognized that the example embodiments can be modified in arrangement and detail without departing from such principles. Also, the foregoing discussion has focused on particular embodiments, but other configurations are also contemplated. In particular, even though expressions such as “in one embodiment”, “in another embodiment,” or the like are used herein, these phrases are meant to generally reference embodiment possibilities, and are not intended to limit the invention to particular embodiment configurations. As used herein, these terms may reference the same or different embodiments that are combinable into other embodiments. As a rule, any embodiment referenced herein is freely combinable with any one or more of the other embodiments referenced herein, and any number of features of different embodiments are combinable with one another, unless indicated otherwise.

Although the invention has been described in considerable detail with reference to certain embodiments, one skilled in the art will appreciate that the present invention can be practiced by other than the described embodiments, which have been presented for purposes of illustration and not of limitation. Therefore, the scope of the appended claims should not be limited to the description of the embodiments contained herein.

What is claimed is:

1. A method for forming a battery, the method comprising:
(a) providing a battery cell structure comprising an anode, an electrolyte, and a cathode including cations that move from the cathode to the anode during charging; and
(b) performing a first charge of the battery cell structure using a predetermined formation protocol to create a formed battery cell,
wherein the predetermined formation protocol is determined by:
(i) determining a first cell internal resistance of a first reference battery cell formed by using a first cell structure identical to the battery cell structure and performing a first initial charge of the first cell structure using a first formation protocol,
(ii) determining a second cell internal resistance of a second reference battery cell formed by using a second cell structure identical to the battery cell structure and performing a second initial charge of the second cell structure using a second formation protocol, wherein the second formation protocol is different from the first formation protocol, and
(iii) selecting the predetermined formation protocol to correspond to the first formation protocol if the first cell internal resistance is greater than or less than the second cell internal resistance, and selecting the predetermined formation protocol to correspond to the second formation protocol if the second cell internal resistance is greater than or less than the first cell internal resistance.

2. The method of claim 1 wherein:
the predetermined formation protocol is selected to correspond to the first formation protocol if the first cell internal resistance is less than the second cell internal resistance, and the predetermined formation protocol is selected to correspond to the second formation protocol if the second cell internal resistance is less than the first cell internal resistance.

3. The method of claim 1 wherein:
the first cell internal resistance and the second cell internal resistance are determined using a direct current resistance measurement.

4. The method of claim 1 wherein:
the first cell internal resistance and the second cell internal resistance are determined using an alternating current resistance measurement.

5. The method of claim 1 wherein:
the battery cell structure provided in step (a) lacks a solid electrolyte interphase between the electrolyte and the anode.

6. The method of claim 1 wherein:
the first cell internal resistance of the first reference battery cell is determined at a first state of charge of the first reference battery cell of 15% or lower, and
the second cell internal resistance of the second reference battery cell is determined at a second state of charge of the second reference battery cell of 15% or lower, wherein the first state of charge and the second state of charge are the same.

7. The method of claim 1 wherein:
the first cell internal resistance of the first reference battery cell is determined using a first series of discharge pulses, and
the second cell internal resistance of the second reference battery cell is determined using a second series of discharge pulses, wherein the first series of discharge pulses and the second series of discharge pulses are the same.

8. The method of claim 7 wherein:
the discharge pulses have a pulse duration less than 1 minute.

9. The method of claim 1 wherein:
the first cell internal resistance of the first reference battery cell is determined using a first series of charge pulses, and
the second cell internal resistance of the second reference battery cell is determined using a second series of charge pulses, wherein the first series of charge pulses and the second series of charge pulses are the same.

10. The method of claim 9 wherein:
the charge pulses have a pulse duration less than 1 minute.

11. The method of claim 1 wherein:
the first cell internal resistance of the first reference battery cell is determined before a second charge of the first reference battery cell, and
the second cell internal resistance of the second reference battery cell is determined before a second charge of the second reference battery cell.

12. The method of claim 1 wherein:
the cations are lithium cations.

13. The method of claim 12 wherein:
the anode comprises an anode material selected from graphite, lithium titanium oxide, hard carbon, tin/cobalt alloys, silicon/carbon, or lithium metal,
the electrolyte comprises a liquid electrolyte including a lithium compound in an organic solvent, and
the cathode comprises a cathode active material selected from (i) lithium metal oxides wherein the metal is one or more aluminum, cobalt, iron, manganese, nickel and vanadium, (ii) lithium-containing phosphates having a general formula LiMPO₄ wherein M is one or more of cobalt, iron, manganese, and nickel, and (iii) materials having a formula LiNiₓMn_{y}Co_{z}O₂, wherein x+y+z=1 and x:y:z=1:1:1 (NMC 111), x:y:z=4:3:3 (NMC 433), x:y:z=5:2:2 (NMC 522), x:y:z=5:3:2 (NMC 532), x:y:z=6:2:2 (NMC 622), or x:y:z=8:1:1 (NMC 811).

14. The method of claim 13 wherein:
the anode comprises graphite,
the lithium compound is selected from LiPF₆, LiBF₄, LiClO₄, lithium bis(fluorosulfonyl)imide (LiFSI), LiN(CF₃SO₂)₂ (LiTFSI), and LiCF₃SO₃ (LiTf),
the organic solvent is selected from carbonate based solvents, ether based solvents, ionic liquids, and mixtures thereof,
the carbonate based solvent is selected from the group consisting of dimethyl carbonate, diethyl carbonate, ethyl methyl carbonate, dipropyl carbonate, methylpropyl carbonate, ethylpropyl carbonate, methylethyl carbonate, ethylene carbonate, propylene carbonate, and butylene carbonate, and mixtures thereof, and
the ether based solvent is selected from the group consisting of diethyl ether, dibutyl ether, monoglyme, diglyme, tetraglyme, 2-methyltetrahydrofuran, tetrahydrofuran, 1,3-dioxolane, 1,2-dimethoxyethane, and 1,4-dioxane and mixtures thereof.

15. The method of claim 1 wherein:
a charging current of the predetermined formation protocol is based at least in part on a percentage of a capacity of the formed battery cell.

16. A method for predicting cycle life of a battery, the method comprising:
(a) providing a battery cell structure comprising an anode, an electrolyte, and a cathode including cations that move from the cathode to the anode during charging;
(b) performing a first charge of the battery cell structure using a predetermined formation protocol to create a formed battery cell;
(c) determining a cell internal resistance of the formed battery cell; and
(d) comparing the cell internal resistance of the formed battery cell to a characteristic curve of measured or model predicted cycle life versus cell internal resistance of reference battery cells formed by using cell structures identical to the battery cell structure and reference formation protocols different from the predetermined formation protocol.

17. The method of claim 16 wherein:
the cell internal resistance is determined using a direct current resistance measurement.

18. The method of claim 16 wherein:
the cell internal resistance is determined using an alternating current resistance measurement.

19. The method of claim 16 wherein:
the battery cell structure provided in step (a) lacks a solid electrolyte interphase between the electrolyte and the anode.

20. The method of claim 16 wherein:
the cell internal resistance of the formed battery cell is determined at a first state of charge of the formed battery cell of 15% or lower.

21. The method of claim 16 wherein:
the cell internal resistance of the formed battery cell is determined using a first series of discharge pulses.

22. The method of claim 21 wherein:
the discharge pulses have a pulse duration less than 1 minute.

23. The method of claim 16 wherein:
the cell internal resistance of the formed battery cell is determined using a first series of charge pulses.

24. The method of claim 23 wherein:
the charge pulses have a pulse duration less than 1 minute.

25. The method of claim 16 wherein:
the cell internal resistance of the formed battery cell is determined before a second charge of the formed battery cell.

26. The method of claim 16 wherein:
the cations are lithium cations.

27. The method of claim 26 wherein:
the anode comprises an anode material selected from graphite, lithium titanium oxide, hard carbon, tin/cobalt alloys, silicon/carbon, or lithium metal,
the electrolyte comprises a liquid electrolyte including a lithium compound in an organic solvent, and
the cathode comprises a cathode active material selected from (i) lithium metal oxides wherein the metal is one or more aluminum, cobalt, iron, manganese, nickel and vanadium, (ii) lithium-containing phosphates having a general formula LiMPO₄ wherein M is one or more of cobalt, iron, manganese, and nickel, and (iii) materials having a formula LiNiₓMn_{y}Co_{z}O₂, wherein x+y+z=1 and x:y:z=1:1:1 (NMC 111), x:y:z=4:3:3 (NMC 433), x:y:z=5:2:2 (NMC 522), x:y:z=5:3:2 (NMC 532), x:y:z=6:2:2 (NMC 622), or x:y:z=8:1:1 (NMC 811).

28. The method of claim 27 wherein:
the anode comprises graphite,
the lithium compound is selected from LiPF₆, LiBF₄, LiClO₄, lithium bis(fluorosulfonyl)imide (LiFSI), LiN(CF₃SO₂)₂ (LiTFSI), and LiCF₃SO₃ (LiTf),
the organic solvent is selected from carbonate based solvents, ether based solvents, ionic liquids, and mixtures thereof,
the carbonate based solvent is selected from the group consisting of dimethyl carbonate, diethyl carbonate, ethyl methyl carbonate, dipropyl carbonate, methylpropyl carbonate, ethylpropyl carbonate, methylethyl carbonate, ethylene carbonate, propylene carbonate, and butylene carbonate, and mixtures thereof, and
the ether based solvent is selected from the group consisting of diethyl ether, dibutyl ether, monoglyme, diglyme, tetraglyme, 2-methyltetrahydrofuran, tetrahydrofuran, 1,3-dioxolane, 1,2-dimethoxyethane, and 1,4-dioxane and mixtures thereof.

29. The method of claim 16 wherein:
a charging current of the predetermined formation protocol is based at least in part on a percentage of a capacity of the formed battery cell.

30. A method for determining whether a first predicted cycle life of a first battery cell is greater than a second predicted cycle life of a second battery cell, the method comprising:
(a) providing a first battery cell structure comprising an anode, an electrolyte, and a cathode including cations that move from the cathode to the anode during charging;
(b) determining a first cell internal resistance of a first battery cell formed by performing a first initial charge of the first battery cell structure using a formation protocol;
(c) determining a second cell internal resistance of a second battery cell formed by performing a second initial charge of a second battery cell structure identical to the first battery cell structure; and
(d) determining that a first predicted cycle life of the first battery cell is greater than a second predicted cycle life of the second battery cell if the first cell internal resistance is greater than or less than the second cell internal resistance.

31. The method of claim 30 wherein:
a first predicted cycle life of the first battery cell is determined to be greater than a second predicted cycle life of the second battery cell if the first cell internal resistance is less than the second cell internal resistance.

32. The method of claim 30 wherein:
the first cell internal resistance and the second cell internal resistance are determined using a direct current resistance measurement.

33. The method of claim 30 wherein:
the first cell internal resistance and the second cell internal resistance are determined using an alternating current resistance measurement.

34. The method of claim 30 wherein:
the first battery cell structure provided in step (a) lacks a solid electrolyte interphase between the electrolyte and the anode.

35. The method of claim 30 wherein:
the first cell internal resistance of the first reference battery cell is determined at a first state of charge of the first reference battery cell of 15% or lower, and
the second cell internal resistance of the second reference battery cell is determined at a second state of charge of the second reference battery cell of 15% or lower, wherein the first state of charge and the second state of charge are the same.

36. The method of claim 30 wherein:
the first cell internal resistance of the first battery cell is determined using a first series of discharge pulses, and
the second cell internal resistance of the second battery cell is determined using a second series of discharge pulses, wherein the first series of discharge pulses and the second series of discharge pulses are the same.

37. The method of claim 36 wherein:
the discharge pulses have a pulse duration less than 1 minute.

38. The method of claim 30 wherein:
the first cell internal resistance of the first battery cell is determined using a first series of charge pulses, and
the second cell internal resistance of the second battery cell is determined using a second series of charge pulses, wherein the first series of charge pulses and the second series of charge pulses are the same.

39. The method of claim 38 wherein:
the charge pulses have a pulse duration less than 1 minute.

40. The method of claim 30 wherein:
the first cell internal resistance of the first battery cell is determined before a second charge of the first battery cell, and
the second cell internal resistance of the second battery cell is determined before a second charge of the second battery cell.

41. The method of claim 30 wherein:
the cations are lithium cations.

42. The method of claim 41 wherein:
the anode comprises an anode material selected from graphite, lithium titanium oxide, hard carbon, tin/cobalt alloys, silicon/carbon, or lithium metal,
the electrolyte comprises a liquid electrolyte including a lithium compound in an organic solvent, and
the cathode comprises a cathode active material selected from (i) lithium metal oxides wherein the metal is one or more aluminum, cobalt, iron, manganese, nickel and vanadium, (ii) lithium-containing phosphates having a general formula LiMPO₄ wherein M is one or more of cobalt, iron, manganese, and nickel, and (iii) materials having a formula LiNiₓMn_{y}Co_{z}O₂, wherein x+y+z=1 and x:y:z=1:1:1 (NMC 111), x:y:z=4:3:3 (NMC 433), x:y:z=5:2:2 (NMC 522), x:y:z=5:3:2 (NMC 532), x:y:z=6:2:2 (NMC 622), or x:y:z=8:1:1 (NMC 811).

43. The method of claim 42 wherein:
the anode comprises graphite,
the lithium compound is selected from LiPF₆, LiBF₄, LiClO₄, lithium bis(fluorosulfonyl)imide (LiFSI), LiN(CF₃SO₂)₂ (LiTFSI), and LiCF₃SO₃ (LiTf),
the organic solvent is selected from carbonate based solvents, ether based solvents, ionic liquids, and mixtures thereof,
the carbonate based solvent is selected from the group consisting of dimethyl carbonate, diethyl carbonate, ethyl methyl carbonate, dipropyl carbonate, methylpropyl carbonate, ethylpropyl carbonate, methylethyl carbonate, ethylene carbonate, propylene carbonate, and butylene carbonate, and mixtures thereof, and
the ether based solvent is selected from the group consisting of diethyl ether, dibutyl ether, monoglyme, diglyme, tetraglyme, 2-methyltetrahydrofuran, tetrahydrofuran, 1,3-dioxolane, 1,2-dimethoxyethane, and 1,4-dioxane and mixtures thereof.

44. The method of claim 30 wherein:
a charging current of the formation protocol is based at least in part on a percentage of a capacity of the formed battery cell.

45. A method for predicting cycle life of a battery, the method comprising:
(a) providing a battery cell structure comprising an anode, an electrolyte, and a cathode including cations that move from the cathode to the anode during charging;
(b) performing a first charge of the battery cell structure using a predetermined formation protocol to create a formed battery cell;
(c) determining a cell internal resistance of the formed battery cell;
(d) determining a cycle life of the formed battery cell by cycling the formed battery cell to an end of life;
(e) repeating steps (a) through (d) for one or more additional battery cell structures; and
(f) training a statistical model taking the cell internal resistance and cycle life of each of the formed battery cell and additional formed battery cells as input and providing a prediction of cycle life for another battery cell.

46. The method of claim 45 wherein:
step (f) further comprises training the statistical model using one or more features selected from: (i) electrical data from the battery formation process, including voltage decay during rest, differential capacity, differential voltage, and (ii) measurements including cell expansion and contraction, and acoustic response.

47. The method of claim 45 wherein:
the cations are lithium cations.

48. A method for optimizing a battery formation protocol, the method comprising:
(a) providing a battery cell structure comprising an anode, an electrolyte, and a cathode including cations that move from the cathode to the anode during charging;
(b) performing a first charge of the battery cell structure using a predetermined formation protocol to create a formed battery cell;
(c) measuring a first group of current-voltage signals during or immediately after the formation protocol;
(d) measuring a second group of current-voltage signals of the formed battery cell after cycling the formed battery cell to an end of life;
(e) repeating steps (a) through (d) for one or more additional battery cell structures; and
(f) creating a statistical model taking the first group of current-voltage signals and the second group of current-voltage signals of each of the formed battery cell and additional formed battery cells as input and providing an optimized battery formation protocol for another battery cell.

49. The method of claim 48 wherein:
step (f) further comprises training the statistical model using one or more features selected from: (i) electrical data from the battery formation process, including voltage decay during rest, differential capacity, differential voltage, and (ii) measurements including cell expansion and contraction, and acoustic response.

50. The method of claim 48 wherein:
the cations are lithium cations.

51. The method of claim 48 wherein:
the anode comprises an anode material selected from graphite, silicon, lithium metal, or a combination thereof,
the electrolyte comprises a liquid electrolyte including a lithium compound and an organic solvent, and
the cathode comprises a cathode active material selected from (i) lithium metal oxides wherein the metal is one or more aluminum, cobalt, iron, manganese, nickel and vanadium, (ii) lithium-containing phosphates having a general formula LiMPO₄ wherein M is one or more of cobalt, iron, manganese, and nickel, and (iii) materials having a formula LiNiₓMn_{y}Co_{z}O₂, wherein x+y+z=1 and x:y:z=1:1:1 (NMC 111), x:y:z=4:3:3 (NMC 433), x:y:z=5:2:2 (NMC 522), x:y:z=5:3:2 (NMC 532), x:y:z=6:2:2 (NMC 622), or x:y:z=8:1:1 (NMC 811).

52. The method of claim 51 wherein:
the anode comprises graphite,
the lithium compound is selected from LiPF₆, LiBF₄, LiClO₄, lithium bis(fluorosulfonyl)imide (LiFSI), LiN(CF₃SO₂)₂ (LiTFSI), and LiCF₃SO₃ (LiTf),
the organic solvent is selected from carbonate based solvents, ether based solvents, ionic liquids, and mixtures thereof,
the carbonate based solvent is selected from the group consisting of dimethyl carbonate, diethyl carbonate, ethyl methyl carbonate, dipropyl carbonate, methylpropyl carbonate, ethylpropyl carbonate, methylethyl carbonate, ethylene carbonate, propylene carbonate, and butylene carbonate, and mixtures thereof, and the ether based solvent is selected from the group consisting of diethyl ether, dibutyl ether, monoglyme, diglyme, tetraglyme, 2 methyltetrahydrofuran, tetrahydrofuran, 1,3-dioxolane, 1,2-dimethoxyethane, and 1,4-dioxane and mixtures thereof.

53. The method of claim 48 wherein:
the formation protocol comprises a charging current based at least in part on a percentage of a capacity of the formed battery cell.

54. The method of claim 53 wherein:
the formation protocol comprises charging or discharging one or more times at fixed or varying states of charge.

55. The method of claim 48 wherein:
the first group of current-voltage signals are processed to calculate a cell internal resistance of the formed battery cell.

56. The method of claim 55 wherein:
the first group of current-voltage signals comprise one or more direct current charge or discharge pulses for up to 1 minute.

57. The method of claim 56 wherein:
the charge or discharge pulses are obtained at states-of-charge less than or equal to 15%.

58. The method of claim 55 wherein:
the first group of current-voltage signals comprise alternating current measurements.

59. The method of claim 58 wherein:
the alternating current resistance measurements are obtained at states-of-charge less than or equal to 15%.

60. The method of claim 55 wherein:
the first group of current-voltage signals comprise a measurement of voltage decay during rest, differential voltage, measurements including cell expansion and contraction, and acoustic response.

61. The method of claim 48 wherein:
the second group of current-voltage signals is measured after a battery capacity of the formed battery cell has decreased to below 80% of an initial capacity of the formed battery cell.

62. The method of claim 61 wherein:
the second group of current-voltage signals are processed to calculate a measured capacity.

63. The method of claim 61 wherein:
the second group of current-voltage signals are processed to calculate a measured cell internal resistance.

64. The method of claim 61 wherein:
the second group of current-voltage signals comprise a measurement of voltage decay during rest, differential voltage, measurements including cell expansion and contraction, and acoustic response.

65. The method of claim 48 wherein:
the statistical model comprises a correlation.

66. The method of claim 48 wherein:
the statistical model comprises a regression model.

67. The method of claim 48 wherein:
the optimized battery formation protocol provides an optimized cycle life for the another battery cell.

68. The method of claim 48 wherein:
the optimized battery formation protocol is determined by comparing resistances measured at states-of-charge less than or equal to 15%.

69. A method for determining the amount of lithium consumed during a battery formation protocol, the method comprising:
(a) providing a battery cell structure comprising an anode, an electrolyte, and a cathode including cations that move from the cathode to the anode during charging;
(b) performing a first charge of the battery cell structure using a predetermined battery formation protocol to create a formed battery cell;
(c) measuring current-voltage signals during or immediately after the battery formation protocol; and
(d) processing the current-voltage signals to calculate the amount of lithium consumed during the battery formation protocol.

70. The method of claim 69 wherein:
the battery formation protocol comprises a charging current based at least in part on a percentage of a capacity of the formed battery cell.

71. The method of claim 69 wherein:
the battery formation protocol comprises charging or discharging one or more times at fixed or varying states of charge.

72. The method of claim 69 wherein:
the current-voltage signals are processed to calculate a cell internal resistance of the formed battery cell.

73. The method of claim 72 wherein:
the current-voltage signals comprise one or more direct current charge or discharge pulses for up to 1 minute.

74. The method of claim 73 wherein:
the charge or discharge pulses are obtained at states-of-charge less than or equal to 15%.

75. The method of claim 72 wherein:
the current-voltage signals comprise alternating current measurements.

76. The method of claim 75 wherein:
the alternating current resistance measurements are obtained at states-of-charge less than or equal to 15%.

77. The method of claim 72 wherein:
the current-voltage signals comprise a measurement of voltage decay during rest, differential voltage, measurements including cell expansion and contraction, and acoustic response.

78. A method for predicting cycle life of a battery, the method comprising:
(a) providing a battery cell structure comprising an anode, an electrolyte, and a cathode including cations that move from the cathode to the anode during charging;
(b) performing a first charge of the battery cell structure using a predetermined formation protocol to create a formed battery cell;
(c) measuring a first group of current-voltage signals during or immediately after the formation protocol of the formed battery cell;
(d) measuring a second group of current-voltage signals by cycling the formed battery cell to an end of life;
(e) repeating steps (a) through (d) for one or more additional battery cell structures; and
(f) creating a statistical model taking the first group of current-voltage signals and the second group of current-voltage signals of each of the formed battery cell and additional formed battery cells as input and providing a prediction of cycle life for another battery cell.

79. The method of claim 78 wherein:
step (f) further comprises creating the statistical model using one or more features selected from: (i) electrical data from the battery formation process, including voltage decay during rest, differential capacity, differential voltage, and (ii) measurements including cell expansion and contraction, and acoustic response.

80. The method of claim 78 wherein:
the formation protocol comprises a charging current based at least in part on a percentage of a capacity of the formed battery cell.

81. The method of claim 80 wherein:
the formation protocol comprises charging or discharging one or more times at fixed or varying states of charge.

82. The method of claim 78 wherein:
the first group of current-voltage signals are processed to calculate a cell internal resistance of the formed battery cell.

83. The method of claim 82 wherein:
the first group of current-voltage signals comprise one or more direct current charge or discharge pulses for up to 1 minute.

84. The method of claim 83 wherein:
the charge or discharge pulses are obtained at states-of-charge less than or equal to 15%.

85. The method of claim 82 wherein:
the first group of current-voltage signals comprise alternating current measurements.

86. The method of claim 85 wherein:
the alternating current resistance measurements are obtained at states-of-charge less than or equal to 15%.

87. The method of claim 82 wherein:
the first group of current-voltage signals comprise a measurement of voltage decay during rest, differential voltage, measurements including cell expansion and contraction, and acoustic response.

88. The method of claim 78 wherein:
the second group of current-voltage signals is measured after a battery capacity of the formed battery cell has decreased to below 80% of an initial capacity of the formed battery cell.

89. The method of claim 88 wherein:
the second group of current-voltage signals are processed to calculate a measured capacity.

90. The method of claim 88 wherein:
the second group of current-voltage signals are processed to calculate a measured cell internal resistance.

91. The method of claim 88 wherein:
the second group of current-voltage signals comprise a measurement of voltage decay during rest, differential voltage, measurements including cell expansion and contraction, and acoustic response.

92. The method of claim 78 wherein:
the statistical model comprises a correlation.

93. The method of claim 78 wherein:
the statistical model comprises a regression model.
